(19) United States
(12) Patent Application Publication
(10) Pub. No.: US 2015/0358569 A1
(43) Pub. Date: Dec. 10, 2015

(54) SOLID-STATE IMAGING DEVICE

(71) Applicant: Kabushiki Kaisha Toshiba, Minato-ku (JP)

(72) Inventor: Yoshitaka EGAWA, Yokohama (JP)

(73) Assignee: Kabushiki Kaisha Toshiba, Minato-ku (JP)

(21) Appl. No.: 14/624,958

(22) Filed: Feb. 18, 2015

(30) Foreign Application Priority Data
Jun. 9, 2014 (JP) 2014-118335

(51) Int. Cl. H04N 5/376; H01L 27/146

(52) U.S. Cl. CPC H04N 5/3765; H01L 27/14612; H01L 27/14645

(57) ABSTRACT

According to one embodiment, a solid-state imaging device includes a pixel that includes a photoelectric conversion unit accumulating charges obtained by photoelectric conversion, the photoelectric conversion unit being disposed in a semiconductor substrate, a photo gate that controls potential of the photoelectric conversion unit from a plane opposite to a light incident plane of the photoelectric conversion unit, a voltage converting unit that converts signal charges read from the photoelectric conversion unit into a voltage, and a conversion capacity control unit that controls a conversion capacity of the voltage converting unit.

### CROSS-REFERENCE TO RELATED APPLICATIONS

This application is based upon and claims the benefit of priority from Japanese Patent Application No. 2014-118335, filed on Jun. 9, 2014; the entire contents of which are incorporated herein by reference.

### FIELD

Embodiments described herein relate generally to a solid-state imaging device.

### BACKGROUND

With the request for downsizing and high image quality of solid-state imaging devices, the pixel size has been reduced. As the pixel size is reduced, a quantity of light incident on pixels is reduced, and particularly, in the low luminance condition, the degradation of an image quality becomes prominent due to white spots, a leakage current, or the like.

### BRIEF DESCRIPTION OF THE DRAWINGS

FIG. 1 is a block diagram illustrating a schematic configuration of a solid-state imaging device according to a first embodiment;

FIG. 2 is a circuit diagram illustrating an exemplary pixel configuration of a Bayer array in a 2-pixel 1-cell configuration of the solid-state imaging device of FIG. 1;

FIG. 3A is a cross-sectional view illustrating the exemplary pixel configuration of FIG. 2, and FIG. 3B is a diagram illustrating a potential distribution of the exemplary configuration of FIG. 3A;

FIG. 4A is a cross-sectional view illustrating a low luminance state of the configuration of FIG. 3A, and FIG. 4B is a diagram illustrating a potential distribution of the state of FIG. 4A;

FIG. 5A is a cross-sectional view illustrating a high luminance state of the configuration of FIG. 3A, and FIG. 5B is a diagram illustrating a potential distribution of the state of FIG. 5A;

FIG. 6 is a circuit diagram illustrating an exemplary pixel configuration of 2×4 pixels in a 2-pixel 1-cell configuration of a solid-state imaging device according to a second embodiment;

FIG. 7A is a timing chart illustrating voltage waveforms of respective components when the pixel of FIG. 6 performs a first read operation, and FIG. 7B is a timing chart illustrating voltage waveforms of respective components when the pixel of FIG. 6 performs a second read operation;

FIG. 8 is a circuit diagram illustrating an exemplary pixel configuration of a Bayer array in a 2-pixel 1-cell configuration of a solid-state imaging device according to a third embodiment;

FIG. 9A is a cross-sectional view illustrating the exemplary pixel configuration of FIG. 8, and FIG. 9B is a diagram illustrating a potential distribution in the exemplary configuration of FIG. 9A;

FIG. 10A is a cross-sectional view illustrating a low luminance state of the configuration of FIG. 9A, and FIG. 10B is a diagram illustrating a potential distribution of the state of FIG. 10A;

FIG. 11A is a cross-sectional view illustrating a high luminance state of the configuration of FIG. 9A, and FIG. 11B is a diagram illustrating a potential distribution of the state of FIG. 11A;

FIG. 12A is a timing chart illustrating voltage waveforms of respective components when the pixel of FIG. 8 performs a first read operation, and FIG. 12B is a timing chart illustrating voltage waveforms of the respective components when the pixel of FIG. 8 performs a second read operation;

FIG. 13 is a block diagram illustrating a schematic configuration of a solid-state imaging device according to a fourth embodiment;

FIG. 14 is a timing chart illustrating voltage waveforms of respective components when the pixel of FIG. 13 performs a read operation.

FIG. 15A is a cross-sectional view illustrating an exemplary pixel configuration of a solid-state imaging device according to a fifth embodiment, and FIG. 15B is a diagram illustrating a potential distribution in the exemplary configuration of FIG. 15A;

FIG. 16A is a cross-sectional view illustrating a charge accumulation state of the configuration of FIG. 15A, and FIG. 16B is a diagram illustrating a potential distribution of the state of FIG. 15A;

FIG. 17 is a timing chart illustrating voltage waveforms of respective components when the pixel of FIG. 15A performs a read operation.

FIG. 18A is a circuit diagram illustrating an exemplary configuration of a switching transistor applied to a solid-state imaging device according to a sixth embodiment, and FIG. 18B is a plane view illustrating an exemplary layout configuration of the switching transistor of FIG. 18A;

FIG. 19 is a circuit diagram illustrating an exemplary pixel configuration of 1×4 pixels in a 2-pixel 1-cell configuration of a solid-state imaging device according to a seventh embodiment;

FIG. 20 is a circuit diagram illustrating an exemplary pixel configuration of 1×4 pixels in a 2-pixel 1-cell configuration of a solid-state imaging device according to an eighth embodiment;

FIG. 21 is a circuit diagram illustrating an exemplary pixel configuration of 1×4 pixels in a 2-pixel 1-cell configuration of a solid-state imaging device according to a ninth embodiment;

FIG. 22 is a circuit diagram illustrating an exemplary pixel configuration of 1×4 pixels in a 2-pixel 1-cell configuration of a solid-state imaging device according to a tenth embodiment;

FIG. 23A is a circuit diagram illustrating an exemplary configuration of a switching transistor applied to a solid-state imaging device according to an eleventh embodiment, and FIG. 23B is a plane view illustrating an exemplary layout configuration of the switching transistor of FIG. 23A;

FIG. 24A is a circuit diagram illustrating an exemplary configuration of a switching transistor applied to a solid-state imaging device according to a twelfth embodiment, and FIG. 24B is a plane view illustrating an exemplary layout configuration of the switching transistor of FIG. 24A;

FIG. 25A is a circuit diagram illustrating an exemplary configuration of a switching transistor applied to a solid-state imaging device according to a thirteenth embodiment, and FIG. 25B is a plane view illustrating an exemplary layout configuration of the switching transistor of FIG. 25A;

FIG. 26A is a circuit diagram illustrating an exemplary configuration of a switching transistor applied to a solid-state imaging device according to a fourteenth embodiment, and FIG. 26B is a plane view illustrating an exemplary layout configuration of the switching transistor of FIG. 26A;

FIG. 27A is a circuit diagram illustrating an exemplary pixel configuration of 1×4 pixels in a 2-pixel 1-cell configuration of a solid-state imaging device according to a fifteenth embodiment, and FIG. 27B is a plane view illustrating an exemplary layout configuration of a division transistor of FIG. 27A;

FIG. 28A is a circuit diagram illustrating an exemplary pixel configuration of 1×4 pixels in a 2-pixel 1-cell configuration of a solid-state imaging device according to a sixteenth embodiment, and FIG. 28B is a plane view illustrating an exemplary layout configuration of a division transistor of FIG. 28A;

FIG. 29 is a timing chart illustrating voltage waveforms of respective components when the pixel of FIGS. 28A and 28B performs a first read operation;

FIG. 30 is a timing chart illustrating voltage waveforms of respective components when the pixel of FIGS. 28A and 28B performs a second read operation;

FIG. 31 is a timing chart illustrating voltage waveforms of respective components when the pixel of FIGS. 28A and 28B performs a third read operation;

FIG. 32 is a block diagram illustrating a schematic configuration of a digital camera to which a solid-state imaging device is applied according to a seventeenth embodiment; and

FIG. 33 is a cross-sectional view illustrating a schematic configuration of a camera module to which a solid-state imaging device is applied according to an eighteenth embodiment.

### DETAILED DESCRIPTION

According to one embodiment, a solid-state imaging device includes a pixel that includes a photoelectric conversion unit accumulating charges obtained by photoelectric conversion, the photoelectric conversion unit being disposed in a semiconductor substrate, a photo gate that controls potential of the photoelectric conversion unit from a plane opposite to a light incident plane of the photoelectric conversion unit, a voltage converting unit that converts signal charges read from the photoelectric conversion unit into a voltage, and a capacity control unit that controls a capacity of the voltage converting unit.

Hereinafter, exemplary embodiments of a solid-state imaging device will be described below in detail with reference to the accompanying drawings. The present invention is not limited to the following embodiments.

### First Embodiment

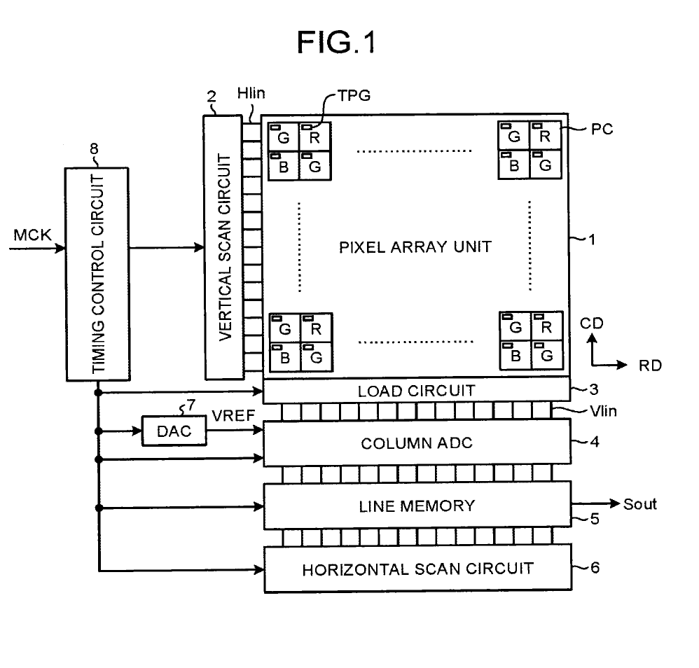

FIG. 1 is a block diagram illustrating a schematic configuration of a solid-state imaging device according to a first embodiment. A backside-illumination type CMOS sensor may be used as the solid-state imaging device.

Referring to FIG. 1, a solid-state imaging device is provided with a pixel array unit 1. In the pixel array unit 1, pixels PC each of which includes photoelectric conversion unit that accumulates charges obtained by photoelectric conversion are arranged in the form of an m×n matrix (m is a positive integer, and n is a positive integer) in which m pixels are arranged in a row direction RD, and n pixels are arranged in a column direction CD. A photo diode may be used as the photoelectric conversion unit. Here, a photo gate TPG is disposed on a plane opposite to a light incident plane of the photoelectric conversion unit of each pixel PC. The photo gate TPG can control potential of the plane opposite to the light incident plane of the photoelectric conversion unit. In the pixel array unit 1, horizontal control lines Hlin used to control reading of the pixels PC are disposed in the row direction RD, and vertical signal lines Vlin used to transfer signals read from the pixels PC are disposed in the column direction CD. The pixel PC may configure the Bayer array including two green pixels Gr and Gb, one red pixel R, and one blue pixel B.

The solid-state imaging device is further provided with a vertical scan circuit 2 that scans the pixels PC of the reading target in the vertical direction, a load circuit 3 that performs a source follower operation with the pixels PC and reads pixel signals from the pixels PC to the vertical signal line Vlin in units of columns, a column ADC circuit 4 that performs a CDS process for extracting only signal components of the pixels PC and performs conversion into a digital signal, a line memory 5 that stores the signal components of the pixels PC detected by the column ADC circuit 4 in units of columns, a horizontal scan circuit 6 that scans the pixels PC of the reading target in the horizontal direction, a reference voltage generating circuit 7 that outputs a reference voltage VREF to the column ADC circuit 4, and a timing control circuit 8 that controls reading timings and accumulation timings of the pixels PC. Here, when the incident light quantity of the photoelectric conversion unit of each pixel PC is small, the timing control circuit 8 can control a voltage of the photo gate TPG such that the potential of the photoelectric conversion unit is shallower than when the incident light quantity of the photoelectric conversion unit of each pixel PC is large. A master clock MCK is input to the timing control circuit 8. A ramp wave may be used as the reference voltage VREF.

The vertical scan circuit 2 scans the pixels PC in the vertical direction in units of lines, and thus the pixels PC are selected in the row direction RD. The load circuit 3 performs the source follower operation with the pixels PC in units of columns, and thus the pixel signals read from the pixels PC are transferred to the column ADC circuit 4 via the vertical signal line Vlin. In the reference voltage generating circuit 7, the ramp wave is set as the reference voltage VREF and transferred to the column ADC circuit 4. The column ADC circuit 4 performs conversion into a digital signal by performing a clock count operation until a signal level and a reset level read from the pixel PC match levels of the ramp wave. At this time, a difference between the signal level and the reset level is obtained, and thus the signal component of each pixel PC is detected through the CDS and output via the line memory 5 as the output signal Sout.

Here, in the low luminance condition, it is possible to control the voltage of the photo gate TPG such that the potential of the photoelectric conversion unit of each pixel PC is shallow, and in the high luminance condition, it is possible to control the voltage of the photo gate TPG such that the potential of the photoelectric conversion unit of each pixel PC is deep. Thus, in the low luminance condition, it is possible to pin the surface side of the photoelectric conversion unit of each pixel PC, and it is possible to reduce the degradation of an image quality caused by white spots, a leakage current, or the like. In the high luminance condition, it is possible to increase a charge accumulation capacity of each pixel PC, it is possible to increase a saturation electron number of each pixel PC, and thus it is possible to reduce the degradation of an image quality caused by a light shot noise.

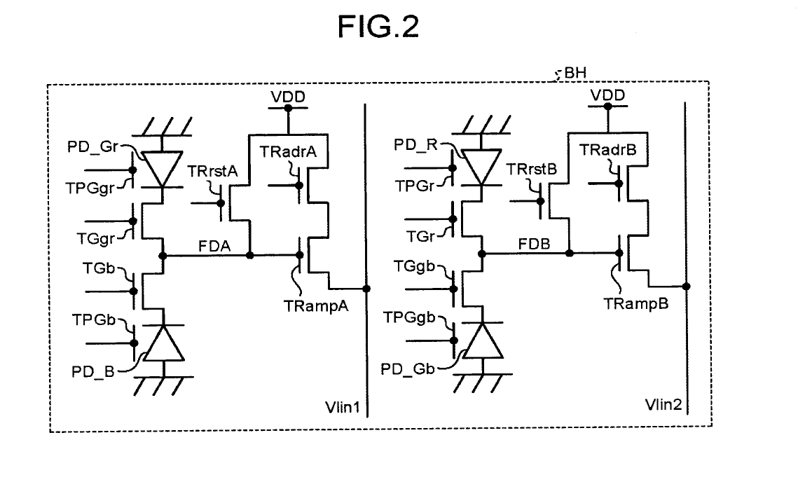

FIG. 2 is a circuit diagram illustrating an exemplary pixel configuration of 2×2 pixels in a 2-pixel 1-cell configuration of the solid-state imaging device of FIG. 1.

Referring to FIG. 2, in a Bayer array BH, a photoelectric conversion unit PD_Gr is disposed for the green pixel Gr, a photoelectric conversion unit PD_B is disposed for the blue pixel B, a photoelectric conversion unit PD_R is disposed for the red pixel R, and the photoelectric conversion unit PD_Gb is disposed for the green pixel Gb. A photo gate TPGgr is disposed in the photoelectric conversion unit PD_Gr, a photo gate TPGb is disposed in the photoelectric conversion unit PD_B, a photo gate TPGr is disposed in the photoelectric conversion unit PD_R, and a photo gate TPGgb is disposed in the photoelectric conversion unit PD_Gb. The Bayer array BH is also provided with row selecting transistors TRadrA and TRadrB, amplifying transistors TRampA and TRampB, reset transistors TRrstA and TRrstB, and read transistors TGgr, TGb, TGr, and TGgb. A floating diffusion FDA is formed at a connection point of the amplifying transistor TRampA, the reset transistor TRrstA, and the read transistors TGgr and TGb as a voltage converting unit. A floating diffusion FDB is formed at a connection point of the amplifying transistor TRampB, the reset transistor TRrstB, and the read transistors TGr and TGgb as a voltage converting unit. Here, a 2-pixel 1-cell configuration is made such that the photoelectric conversion units PD_Gr and PD_B share the floating diffusion FDA, and a 2-pixel 1-cell configuration is made such that the photoelectric conversion units PD_R and PD_Gb share the floating diffusion FDB.

The photoelectric conversion unit PD_Gr is connected to the floating diffusion FDA via the read transistor TGgr, and the photoelectric conversion unit PD_B is connected to the floating diffusion FDA via the read transistor TGb. A gate of the amplifying transistor TRampA is connected to the floating diffusion FDA, a source of the amplifying transistor TRampA is connected to a vertical signal line Vlin1 via the row selecting transistor TRadrA, and a drain of the amplifying transistor TRampA is connected to a power potential VDD. The floating diffusion FDA is connected to the power potential VDD via the reset transistor TRrstA.

The photoelectric conversion unit PD_R is connected to the floating diffusion FDB via the read transistor TGr, and the photoelectric conversion unit PD_Gb is connected to the floating diffusion FDB via the read transistor TGgb. A gate of the amplifying transistor TRampB is connected to the floating diffusion FDB, a source of the amplifying transistor TRampB is connected to a vertical signal line Vlin2 via the row selecting transistor TRadrB, and a drain of the amplifying transistor TRampB is connected to the power potential VDD. The floating diffusion FDB is connected to the power potential VDD via the reset transistor TRrstB. Signals can be input to the gates of the row selecting transistors TRadrA and TRadrB, the reset transistors TRrstA and TRrstB, and the read transistors TGgr, TGb, TGr, and TGgb and the photo gates TPGgr, TPGb, TPGr, and TPGgb via the horizontal control lines Hlin.

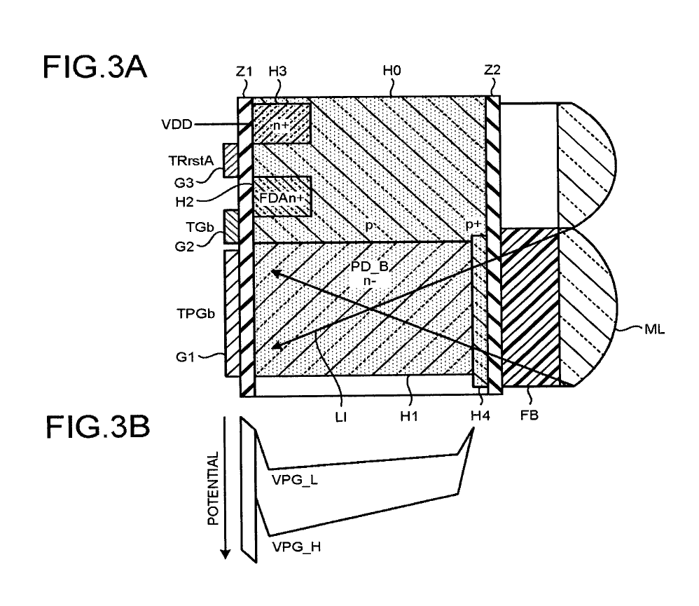

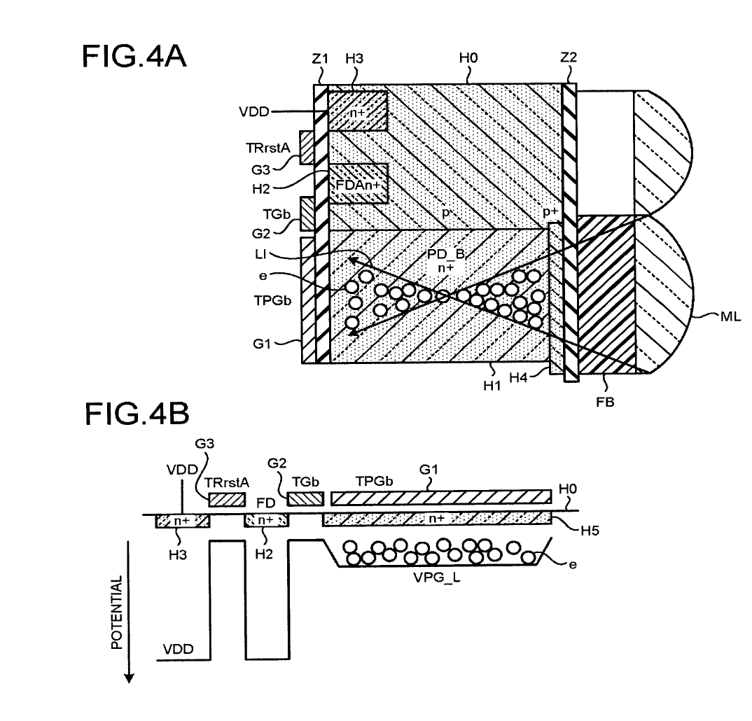

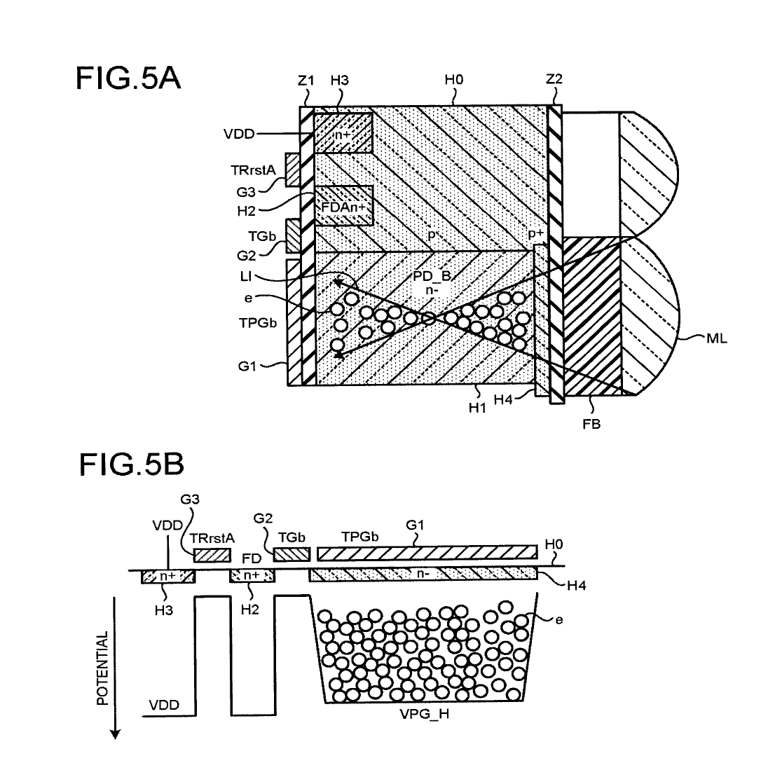

FIG. 3A is a cross-sectional view illustrating the exemplary pixel configuration of FIG. 2, FIG. 3B is a diagram illustrating a potential distribution of the exemplary configuration of FIG. 3A, FIG. 4A is a cross-sectional view illustrating a low luminance state of the configuration of FIG. 3A, FIG. 4B is a diagram illustrating a potential distribution (a deepest potential cross section) of the state of FIG. 4A, FIG. 5A is a cross-sectional view illustrating a high luminance state of the configuration of FIG. 3A, and FIG. 5B is a diagram illustrating a potential distribution (the deepest potential cross section) of the state of FIG. 5A. FIGS. 3A to 5A illustrate a schematic configuration of the blue pixel B of FIG. 1.

Referring to FIG. 3A, an insulating film Z1 is formed on a front surface of a semiconductor layer H0, and an insulating film Z2 is formed on a back surface of the semiconductor layer H0. For example, a material of the semiconductor layer H0 may be selected from Si, Ge, SiGe, SiC, SiSn, PbS, GaAs, InP, InGaAsP, GaP, GaN, ZnSe, or the like. For example, a silicon oxide film may be used as a material of the insulating films Z1 and Z2. The photoelectric conversion unit PD_B is formed such that a diffusion layer H1 is formed to range from the front surface of the semiconductor layer H0 to the back surface thereof. A pinning layer H4 is formed at the back surface side of the diffusion layer H1. The floating diffusion FDA is formed such that a diffusion layer H2 is formed at the front surface side of the semiconductor layer H0, apart from the diffusion layer H1. A diffusion layer H3 is formed at the front surface side of the semiconductor layer H0, apart from the diffusion layer H2, and the diffusion layer H3 is connected to the power potential VDD. The semiconductor layer H0 may be set to a p type. The diffusion layer H1 may be set to an n⁻ type. The diffusion layers H2 and H3 may be set to an n⁺ type. The pinning layer H4 may be set to a p⁺ type. The photo gate TPGb is formed such that a gate electrode G1 is formed above the diffusion layer H1 with the insulating film Z1 interposed therebetween. The read transistor TGb is formed such that a gate electrode G2 is formed between the diffusion layers H1 and H2 with the insulating film Z1 interposed therebetween. A gap of 1 μm or less may be formed between the gate electrodes G1 and G2, and end portions of the gate electrodes G1 and G2 may overlap. The reset transistor TRrstA is formed such that a gate electrode G3 is formed between the diffusion layers H2 and H3 with the insulating film Z2 interposed therebetween. As a material of the gate electrodes G1 to G3, for example, a poly crystalline silicon may be used, and metal such as Cu, Al, or W may be used. A blue filter FB is formed at the back surface side of the diffusion layer H1 with the insulating film Z2 interposed therebetween, and a micro lens ML is formed on the blue filter FB.

Among components of incident light LI condensed through the micro lens ML, blue light is selected through the blue filter FB and incident on the diffusion layer H1. Then, as illustrated in FIGS. 4A and 5A, in the diffusion layer H1, the incident light LI is converted into charges e, and the charges e are accumulated in the diffusion layer H1. As the gate electrode G1 is formed of a material having a high reflectance such as metal, the incident light LI incident on the diffusion layer H1 can be reflected by the photo gate TPGb, and use efficiency of the incident light LI can be improved.

Here, in the low luminance condition, the voltage of the photo gate TPGb can be set to VPG_L so that the potential of the photoelectric conversion unit PD_B is shallow as illustrated in FIGS. 3B and 4B. At this time, the voltage VPG_L of the photo gate TPGb can be set to 0 V or −1 to −2 V. As a result, a p⁺ type pinning layer H5 can be formed on the front surface side of the photoelectric conversion unit PD_B, and it is possible to reduce the degradation of an image quality caused by white spots, a leakage current, or the like.

Meanwhile, in the high luminance condition, the voltage of the photo gate TPGb can be set to VPG_H so that the potential of the photoelectric conversion unit PD_B is deep as illustrated in FIGS. 3B and 5B. At this time, the voltage VPG_H of the photo gate TPGb can be set to 3 to 5 V. As a result, it is possible to increase the charge accumulation capacity of the photoelectric conversion unit PD_B, it is possible to increase the saturation electron number of the photoelectric conversion unit PD_B, and thus it is possible to reduce the degradation of an image quality caused by the light shot noise.

Further, in the intermediate luminance condition, the voltage VPG_M of the photo gate TPGb may be controlled so that the potential of the photoelectric conversion unit PD_B has an intermediate level. At this time, the voltage VPG_M of the photo gate TPGb can be set to 1 to 3 V. As a result, it is possible to balance the degradation of an image quality caused by white spots, a leakage current, or the like and the degradation of an image quality caused by the light shot noise.

### Second Embodiment

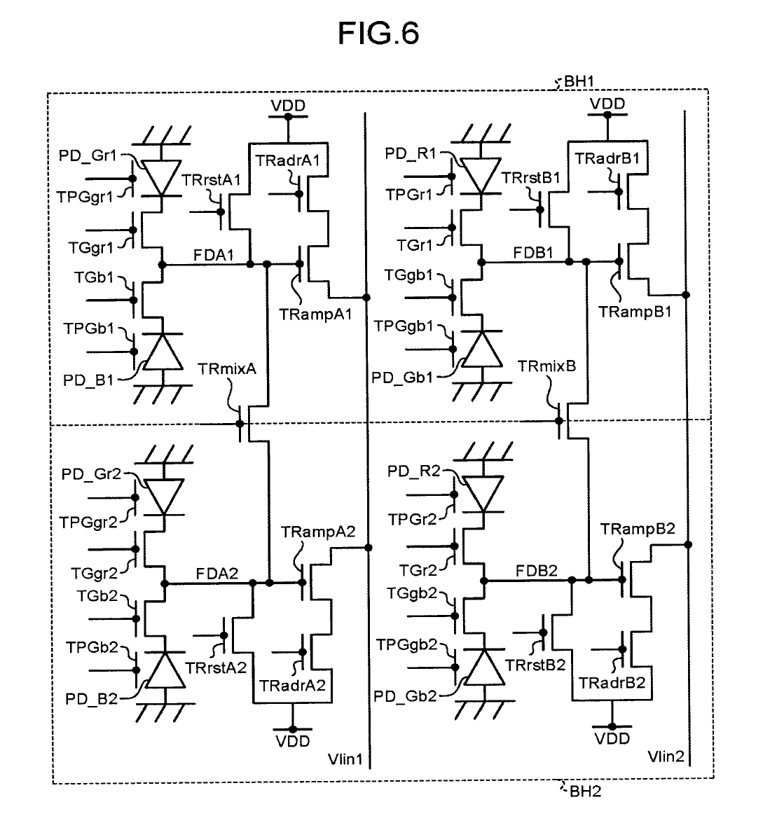

FIG. 6 is a circuit diagram illustrating an exemplary pixel configuration of 2×4 pixels in a 2-pixel 1-cell configuration of a solid-state imaging device according to a second embodiment.

Referring to FIG. 6, in the solid-state imaging device, switching transistors TRmixA and TRmixB for changing the capacity of the voltage converting unit that converts charges generated by the pixel into a voltage are disposed between the pixels PC. The switching transistors TRmixA and TRmixB may be disposed between the pixels PC neighboring in the column direction CD. If a pixel configuration in which the voltage converting unit that converts charges accumulated in the pixel PC into a voltage is shared by a plurality of pixels PC is defined to be a cell, the switching transistors TRmixA and TRmixB may be disposed between the cells.

Here, in the low luminance condition, it is possible to control the voltage of the photo gate TPG such that the potential of the photoelectric conversion unit of each pixel PC is shallow and turn off the switching transistors TRmixA and TRmixB. As a result, it is possible to pin the front surface side of the photoelectric conversion unit of each pixel PC, it is possible to reduce the degradation of an image quality caused by white spots, a leakage current, or the like, it is possible to decrease the capacity of the voltage converting unit that converts charges accumulated in the pixel PC into a voltage, it is possible to improve a conversion gain of converting the charges into a voltage, and thus it is possible to improve an SN ratio. At this time, if the capacity of the voltage converting unit is Cfd, an amount of charges accumulated in the voltage converting unit is Qsig, and a voltage converted by the voltage converting unit is Vsig, it can be represented by Vsig=Qsig/Cfd.

In the high luminance condition, it is possible to control the voltage of the photo gate TPG such that the potential of the photoelectric conversion unit of each pixel PC is deep, and it is possible to turn on the switching transistors TRmixA and TRmixB. As a result, it is possible to increase the charge accumulation capacity of the photoelectric conversion unit, it is possible to increase the saturation electron number of the voltage converting unit to be twice or more, and it is possible to increase the dynamic range.

Next, a connection relation between the switching transistors TRmixA and TRmixB will be specifically described. Here, Bayer arrays BH1 and BH2 are assumed to be arranged to be adjacent to each other in the column direction CD.

In the Bayer array BH1, a photoelectric conversion unit PD_Gr1 is disposed for the green pixel Gr, a photoelectric conversion unit PD_B1 is disposed for the blue pixel B, a photoelectric conversion unit PD_R1 is disposed for the red pixel R, and a photoelectric conversion unit PD_Gb1 is disposed for the green pixel Gb. A photo gate TPGgr1 is disposed in the photoelectric conversion unit PD_Gr1, a photo gate TPGb1 is disposed in the photoelectric conversion unit PD_B1, a photo gate TPGr1 is disposed in the photoelectric conversion unit PD_R1, and a photo gate TPGgb1 is disposed in the photoelectric conversion unit PD_Gb1. Further, in the Bayer array BH1, row selecting transistors TRadrA1 and TRadrB1, amplifying transistors TRampA1 and TRampB1, reset transistors TRrstA1 and TRrstB1, and read transistors TGgr1, TGb1, TGr1, and TGgb1 are disposed. A floating diffusion FDA1 is formed at a connection point of the amplifying transistor TRampA1, the reset transistor TRrstA1, and the read transistors TGgr1 and TGb1 as the voltage converting unit. A floating diffusion FDB1 is formed at a connection point of the amplifying transistor TRampB1, the reset transistor TRrstB1, and the read transistors TGr1 and TGgb1 as the voltage converting unit.

The photoelectric conversion unit PD_Gr1 is connected to the floating diffusion FDA1 via the read transistor TGgr1, and the photoelectric conversion unit PD_B1 is connected to the floating diffusion FDA1 via the read transistor TGb1. A gate of the amplifying transistor TRampA1 is connected to the floating diffusion FDA1, a source of the amplifying transistor TRampA1 is connected to a vertical signal line Vlin1 via the row selecting transistor TRadrA1, and a drain of the amplifying transistor TRampA1 is connected to the power potential VDD. The floating diffusion FDA1 is connected to the power potential VDD via the reset transistor TRrstA1.

The photoelectric conversion unit PD_R1 is connected to the floating diffusion FDB1 via the read transistor TGr1, and the photoelectric conversion unit PD_Gb1 is connected to the floating diffusion FDB1 via the read transistor TGgb1. A gate of the amplifying transistor TRampB1 is connected to the floating diffusion FDB1, a source of the amplifying transistor TRampB1 is connected to a vertical signal line Vlin2 via the row selecting transistor TRadrB1, and a drain of the amplifying transistor TRampB1 is connected to the power potential VDD. The floating diffusion FDB1 is connected to the power potential VDD via the reset transistor TRrstB1.

In the Bayer array BH2, a photoelectric conversion unit PD_Gr2 is disposed for the green pixel Gr, a photoelectric conversion unit PD_B2 is disposed for the blue pixel B, a photoelectric conversion unit PD_R2 is disposed for the red pixel R, and a photoelectric conversion unit PD_Gb2 is disposed for the green pixel Gb. A photo gate TPGgr2 is disposed in the photoelectric conversion unit PD_Gr2, a photo gate TPGb2 is disposed in the photoelectric conversion unit PD_B2, a photo gate TPGr2 is disposed in the photoelectric conversion unit PD_R2, and a photo gate TPGgb2 is disposed in the photoelectric conversion unit PD_Gb2. Further, in the Bayer array BH2, row selecting transistors TRadrA2 and TRadrB2, amplifying transistors TRampA2 and TRampB2, reset transistors TRrstA2 and TRrstB2, and read transistors TGgr2, TGb2, TGr2, and TGgb2 are disposed. A floating diffusion FDA2 is formed at a connection point of the amplifying transistor TRampA2, the reset transistor TRrstA2, and the read transistors TGgr2 and TGb2 as the voltage converting unit. A floating diffusion FDB2 is formed at a connection point of the amplifying transistor TRampB2, the reset transistor TRrstB2, and the read transistors TGr2 and TGgb2 as the voltage converting unit.

The photoelectric conversion unit PD_Gr2 is connected to the floating diffusion FDA2 via the read transistor TGgr2, and the photoelectric conversion unit PD_B2 is connected to the floating diffusion FDA2 via the read transistor TGb2. A gate of the amplifying transistor TRampA2 is connected to the floating diffusion FDA2, a source of the amplifying transistor TRampA2 is connected to the vertical signal line Vlin1 via the row selecting transistor TRadrA2, and a drain of the amplifying transistor TRampA2 is connected to the power potential VDD. The floating diffusion FDA2 is connected to the power potential VDD via the reset transistor TRrstA2.

The photoelectric conversion unit PD_R2 is connected to the floating diffusion FDB2 via the read transistor TGr2, and the photoelectric conversion unit PD_Gb2 is connected to the floating diffusion FDB2 via the read transistor TGgb2. A gate of the amplifying transistor TRampB2 is connected to the floating diffusion FDB2, a source of the amplifying transistor TRampB2 is connected to the vertical signal line Vlin2 via the row selecting transistor TRadrB2, and a drain of the amplifying transistor TRampB2 is connected to the power potential VDD. The floating diffusion FDB2 is connected to the power potential VDD via the reset transistor TRrstB2. Further, signals can be input to the gates of the row selecting transistors TRadrA1, TRadrB1, TRadrA2, and TRadrB2, the reset transistors TRrstA1, TRrstB1, TRrstA2, and TRrstB2 and the read transistors TGgr1, TGb1, TGr1, TGgb1, TGgr2, TGb2, TGr2, and TGgb2 via the horizontal control lines H1in.

The floating diffusions FDA1 and FDA2 are connected to each other via the switching transistor TRmixA, and the floating diffusions FDB1 and FDB2 are connected to each other via the switching transistor TRmixB.

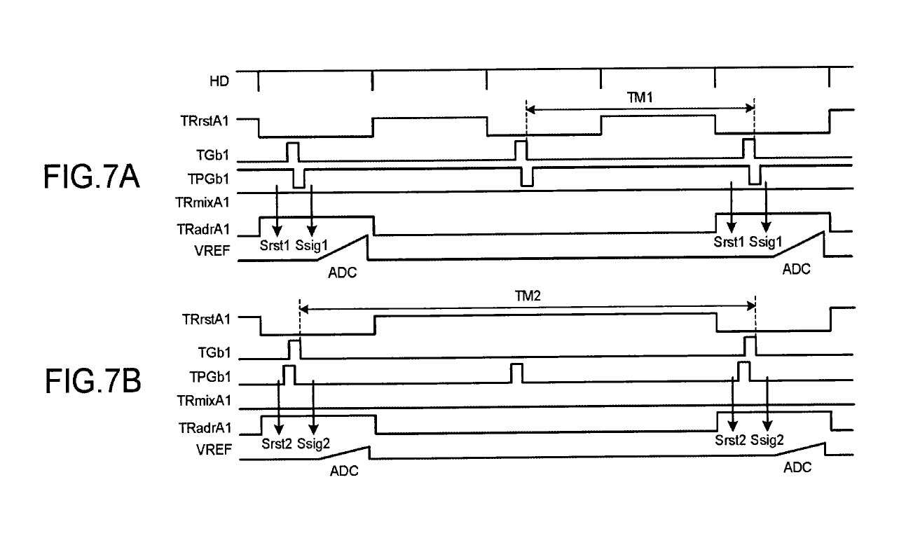

FIG. 7A is a timing chart illustrating voltage waveforms of the respective components when the pixel of FIG. 6 performs a first read operation, and FIG. 7B is a timing chart illustrating voltage waveforms of the respective components when the pixel of FIG. 6 performs a second read operation. The examples of FIGS. 7A and 7B illustrate the read operations of the photoelectric conversion unit PD_B1 of FIG. 6.

In FIG. 7A, in the first read operation, as the switching transistor TRmixA is turned on, the floating diffusions FDA1 and FDA2 are connected with each other. Further, during the charge accumulation operation, the voltage of the photo gate TPG is set to VPG_H.

Then, as the read transistor TGb1 is turned on, residual charges of the photoelectric conversion unit PD_B1 are discharged to the floating diffusion FDA′. Thereafter, as the read transistor TGb1 is turned off, an operation of accumulating signal charges in the photoelectric conversion unit PD_B starts. Then, as the reset transistor TRrstA1 is turned on, the charges of the floating diffusion FDA1 are discharged, and then the reset transistor TRrstA1 is turned off.

Then, the row selecting transistor TRadrA1 is turned on when the read transistor TGb1 is in the off state, and thus the amplifying transistor TRampA1 performs the source follower operation, and a voltage according to charges of a black level of the floating diffusion FDA1 is read out to the vertical signal line Vlin1. Then, a pixel signal Srst1 of a black level is detected based on the voltage of the vertical signal line Vlin1 at this time. Thereafter, as the read transistor TGb1 is turned on, the signal charges of the photoelectric conversion unit PD_B1 is read out to the floating diffusion FDA1. Then, the amplifying transistor TRampA1 performs the source follower operation, and thus a voltage according to charges of a signal level of the floating diffusion FDA1 is read out to the vertical signal line Vlin1. Then, the pixel signal Ssig1 of the signal level is detected based on the voltage of the vertical signal line Vlin1 at this time. Then, a difference between the pixel signal Ssig1 of the signal level and the pixel signal Srst1 of the black level is obtained, and a signal component according to the charges accumulated in the photoelectric conversion unit PD_B1 is detected. At this time, the accumulation period of time of the photoelectric conversion unit PD_B1 is TM1. The pixel signal Srst1 of the black level and the pixel signal Ssig1 of the signal level are sequentially read in synchronization with a horizontal synchronous signal HD. In order to form a potential gradient from the photoelectric conversion unit PD_B to the floating diffusion FDA1, when the read transistor TGb1 transitions from the on state to the off state, the voltage of the photo gate TPGb1 may be temporarily fallen.

Here, in the first read operation, it is possible to cause the potential of the photoelectric conversion unit PD_B1 to be deep through the photo gate TPG, it is possible to connect the floating diffusions FDA1 and FDA2 with each other through the switching transistor TRmixA, and it is possible to increase the saturation electron number of the pixel PC.

Meanwhile, in FIG. 7B, in the second read operation, as the switching transistor TRmixA is turned off, the floating diffusions FDA1 and FDA2 are separated from each other. Further, during the charge accumulation operation, the voltage of the photo gate TPG is set to VPG_L.

Then, as the read transistor TGb1 is turned on, the residual charges of the photoelectric conversion unit PD_B1 are discharged to the floating diffusion FDA1. Thereafter, as the read transistor TGb1 is turned off, an operation of accumulating the signal charges in the photoelectric conversion unit PD_B starts. Then, as the reset transistor TRrstA1 is turned on, the charges of the floating diffusion FDA1 are discharged, and then the reset transistor TRrstA1 is turned off.

Then, the row selecting transistor TRadrA1 is turned on when the read transistor TGb1 is in the off state, the amplifying transistor TRampA1 performs the source follower operation, a voltage according to the charges of the black level of the floating diffusion FDA1 is read out to the vertical signal line Vlin1. Then, a pixel signal Srst2 of the black level is detected based on the voltage of the vertical signal line Vlin1 at this time. Thereafter, the read transistor TGb1 is turned on, and the signal charges of the photoelectric conversion unit PD_B1 are read out to the floating diffusion FDA1. Then, the amplifying transistor TRampA1 performs the source follower operation, and thus a voltage according to the charges of the signal level of the floating diffusion FDA1 is read out to the vertical signal line Vlin1. Then, a pixel signal Ssig2 of the signal level is detected based on the voltage of the vertical signal line Vlin1 at this time. Then, a difference between the pixel signal Ssig2 of the signal level and the pixel signal Srst2 of the black level is obtained, and thus a signal component according to the charges accumulated in the photoelectric conversion unit PD_B1 is detected. At this time, the accumulation period of time of the photoelectric conversion unit PD_B1 is TM2. In order to form the potential gradient from the back surface side of the photoelectric conversion unit PD_B to the front surface side thereof, when the read transistor TGb1 transitions from the off state to the on state, the voltage of the photo gate TPGb1 may be temporarily raised.

Here, in the second read operation, it is possible to cause the potential of the photoelectric conversion unit PD_B1 to be shallow through the photo gate TPG, it is possible to separate the floating diffusions FDA1 and FDA2 from each other through the switching transistor TRmixA, it is possible to reduce the degradation of an image quality caused by white spots, a leakage current, or the like, and it is possible to improve an SN ratio.

### Third Embodiment

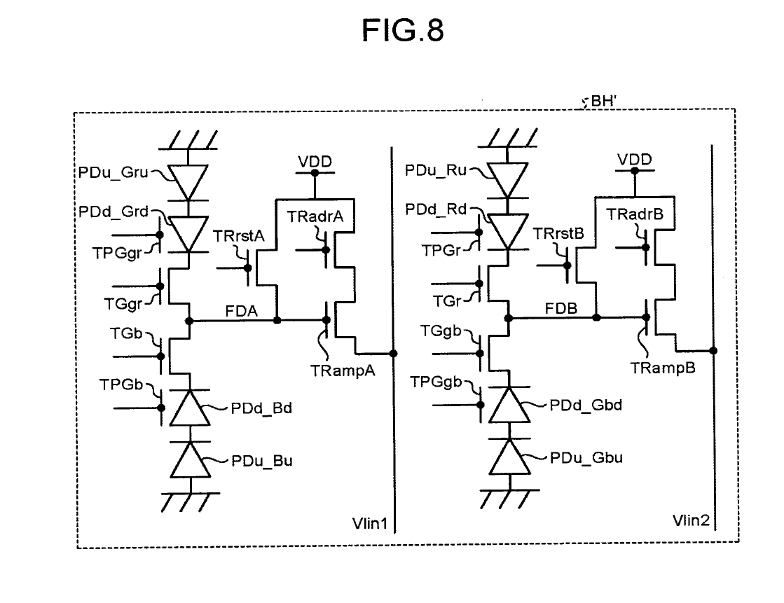

FIG. 8 is a circuit diagram illustrating an exemplary pixel configuration of a Bayer array in a 2-pixel 1-cell configuration of a solid-state imaging device according to a third embodiment. In the solid-state imaging device, a Bayer array BH′ is provided instead of the Bayer array BH of FIG. 2. In the Bayer array BH′, photoelectric conversion units PDd_Grd and PDu_Gru are disposed as the photoelectric conversion unit PD_Gr, photoelectric conversion units PDd_Bd and PDu_Bu are disposed as the photoelectric conversion unit PD_B, photoelectric conversion units PDd_Rd and PDu_Ru are disposed as the photoelectric conversion unit PD_R, and photoelectric conversion units PDd_Gbd and PDu_Gbu are disposed as the photoelectric conversion unit PD_Gb. A photo gate TPGgr is disposed in the photoelectric conversion unit PDd_Grd, a photo gate TPGb is disposed in the photoelectric conversion unit PDd_Bd, a photo gate TPGr is disposed in the photoelectric conversion unit PDd_Rd, and a photo gate TPGgb is disposed in the photoelectric conversion unit PDd_Gbd.

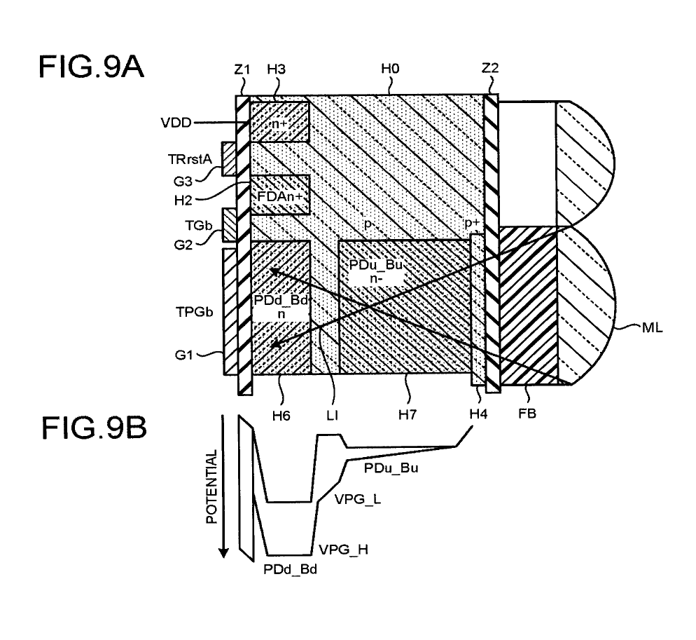

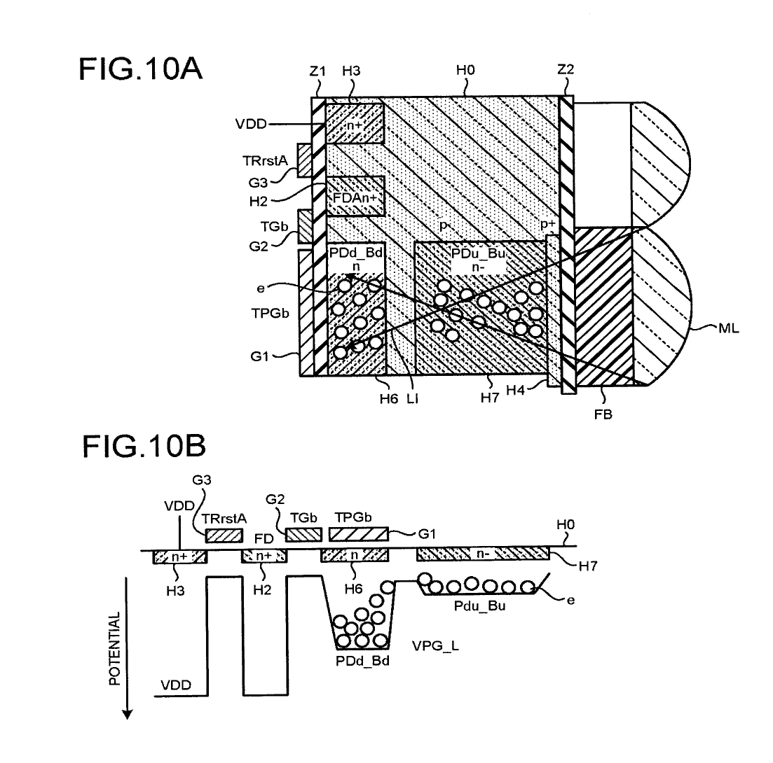

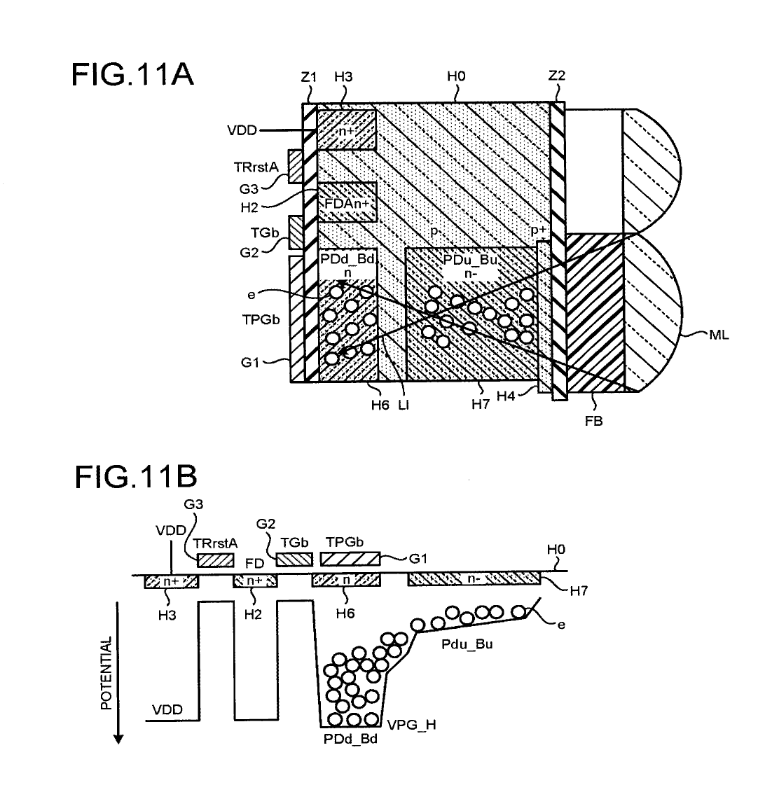

FIG. 9A is a cross-sectional view illustrating the exemplary pixel configuration of FIG. 8, FIG. 9B is a diagram illustrating a potential distribution in the exemplary configuration of FIG. 9A, FIG. 10A is a cross-sectional view illustrating a low luminance state of the configuration of FIG. 9A, FIG. 10B is a diagram illustrating a potential distribution of the state of FIG. 10A, FIG. 11A is a cross-sectional view illustrating a high luminance state of the configuration of FIG. 9A, and FIG. 11B is a diagram illustrating a potential distribution of the state of FIG. 11A. FIGS. 9A to 11A illustrate the schematic configuration of the blue pixel B of FIG. 1.

In FIG. 9A, in this exemplary configuration, diffusion layers H6 and H7 are disposed instead of the diffusion layer H1 of FIG. 3A. The diffusion layer H6 is arranged at the front surface side of the semiconductor layer H0, and the diffusion layer H7 is arranged at the back surface side of the semiconductor layer H0. The diffusion layers H6 and H7 are arranged to overlap. Here, impurity concentrations of the diffusion layers H6 and H7 can be set so that a potential gradient is formed from the back surface side of the semiconductor layer H0 to the front surface side thereof. Further, it is possible to cause the potential of the diffusion layer H6 to be deep so that the saturation electron number is increased, and it is possible to cause the potential of the diffusion layer H7 to be shallow so that a leakage current is reduced. For example, the diffusion layer H6 may be set to an n type, and the diffusion layer H7 may be set to an n⁻ type.

Among the incident light LI condensed through the micro lens ML, blue light is selected through the blue filter FB and incident on the diffusion layers H6 and H7. As illustrated in FIG. 10A and FIG. 11A, in the diffusion layers H6 and H7, the incident light LI is converted into the charges e, and the charges e are accumulated in the diffusion layers H6 and H7.

Here, in the low luminance condition and the intermediate luminance condition, it is possible to set the voltage of the photo gate TPGb to VPG_L and form a potential barrier between the photoelectric conversion units PDd_Bd and PDu_Bu so that the potential of the photoelectric conversion unit PDd_Bd is shallow as illustrated in FIG. 9B and FIG. 10B. Further, in the low luminance condition, after the charges e accumulated in the photoelectric conversion unit PDd_Bd are discharged, it is possible to read the charges e accumulated in the photoelectric conversion unit PDu_Bu. As a result, it is possible to reduce influence of charges caused by white spots, a leakage current, or the like at the time of signal detection, and it is possible to reduce the degradation of an image quality caused by white spots, a leakage current, or the like. In the intermediate luminance condition, it is possible to add and read the charges e accumulated in the photoelectric conversion units PDd_Bd and PDu_Bu. As a result, it is possible to reduce the degradation of an image quality caused by white spots, a leakage current, or the like while suppressing a reduction in the saturation electron number.

Meanwhile, in the high luminance condition, it is possible to set the voltage of the photo gate TPGb to VPG_H and form the potential gradient from the photoelectric conversion unit PDu_Bu to the photoelectric conversion unit PDd_Bd so that the potential of the photoelectric conversion unit PDd_Bd is deep as illustrated in FIG. 9B and FIG. 11B. As a result, it is possible to couple the capacities of the photoelectric conversion units PDd_Bd and PDu_Bu, and it is possible to increase the saturation electron number of the pixel PC.

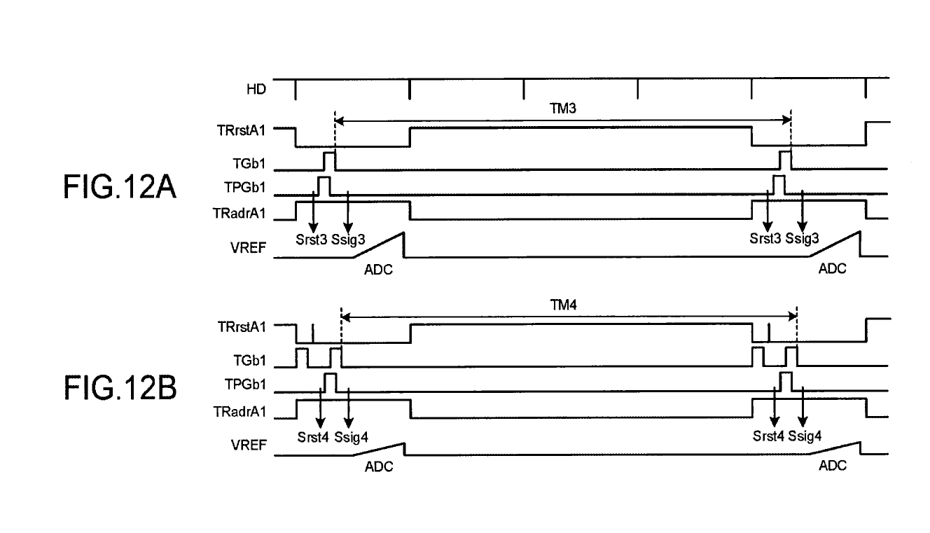

FIG. 12A is a timing chart illustrating voltage waveforms of the respective components when the pixel of FIG. 8 performs a first read operation, and FIG. 12B is a timing chart illustrating voltage waveforms of the respective components when the pixel of FIG. 8 performs a second read operation. The examples of FIGS. 12A and 12B illustrate the read operations of the photoelectric conversion units PDd_Bd and PDu_Bu of FIG. 8. The first read operation can be applied in the intermediate luminance condition, and the second read operation can be applied in the low luminance condition. In the high luminance condition, the timing chart of FIG. 7A can be applied. In FIG. 12A, in the first read operation, the voltage of the photo gate TPGb1 is set to VPG_L during the charge accumulation operation.

Then, as the read transistor TGb1 is turned on, the residual charges of the photoelectric conversion units PDd_Bd and PDu_Bu are discharged to the floating diffusion FDA1. Thereafter, as the read transistor TGb1 is turned off, an operation of accumulating the signal charges in the photoelectric conversion units PDd_Bd and PDu_Bu starts. Then, as the reset transistor TRrstA1 is turned on, the charges of the floating diffusion FDA1 are discharged, and then the reset transistor TRrstA1 is turned off.

Then, the row selecting transistor TRadrA1 is turned on when the read transistor TGb1 is in the off state, and thus the amplifying transistor TRampA1 performs the source follower operation, the voltage according to the charges of the black level of the floating diffusion FDA1 is read out to the vertical signal line Vlin1. Then, a pixel signal Srst3 of the black level is detected based on the voltage of the vertical signal line Vlin1 at this time. Thereafter, the read transistor TGb1 is turned on, and the signal charges of the photoelectric conversion units PDd_Bd and PDu_Bu are read out to the floating diffusion FDA1. Then, the amplifying transistor TRampA1 performs the source follower operation, and thus the voltage according to the charges of the signal level of the floating diffusion FDA1 is read out to the vertical signal line Vlin1. Then, a pixel signal Ssig3 of the signal level is detected based on the voltage of the vertical signal line Vlin1 at this time. Then, a difference between the pixel signal Ssig3 of the signal level and the pixel signal Srst3 of the black level is obtained, and thus signal components according to the charges accumulated in the photoelectric conversion units PDd_Bd and PDu_Bu are detected. At this time, the accumulation period of time of the photoelectric conversion unit PD_B1 is TM3. Further, in order to form the potential gradient from the photoelectric conversion unit PDu_Bu to the photoelectric conversion unit PDd_Bd, when the read transistor TGb1 transitions from the off state to the on state, the voltage of the photo gate TPGb1 may be temporarily raised.

Meanwhile, in FIG. 12B, in the second read operation, the voltage of the photo gate TPGb1 is set to VPG_L during the charge accumulation operation.

Then, as the read transistor TGb1 is turned on, the residual charges of the photoelectric conversion units PDd_Bd and PDu_Bu are discharged to the floating diffusion FDA1. Thereafter, as the read transistor TGb1 is turned off, an operation of accumulating the signal charges in the photoelectric conversion units PDd_Bd and PDu_Bu start. Then, as the reset transistor TRrstA1 is turned on, the charges of the floating diffusion FDA1 are discharged, and then the reset transistor TRrstA1 is turned off.

Next, as the read transistor TGb1 is turned on, the charges accumulated in the photoelectric conversion unit PDd_Bd are discharged to the floating diffusion FDA1. Thereafter, after the read transistor TGb1 is off, the reset transistor TRrstA1 is turned on, and thus the charges of the floating diffusion FDA1 are discharged, and the reset transistor TRrstA1 is turned off.

Then, the row selecting transistor TRadrA1 is turned on when the read transistor TGb1 is in the off state, and thus the amplifying transistor TRampA1 performs the source follower operation, the voltage according to the charges of the black level of the floating diffusion FDA1 is read out to the vertical signal line Vlin1. Then, a pixel signal Srst4 of the black level is detected based on the voltage of the vertical signal line Vlin1 at this time. Thereafter, as the read transistor TGb1 is turned on, the signal charges of the photoelectric conversion unit PDu_Bu are read out to the floating diffusion FDA1. Then, the amplifying transistor TRampA1 performs the source follower operation, and thus the voltage according to the charges of the signal level of the floating diffusion FDA1 is read out to the vertical signal line Vlin1. Then, a pixel signal Ssig4 of the signal level is detected based on the voltage of the vertical signal line Vlin1 at this time. Then, a difference between the pixel signal Ssig4 of the signal level and the pixel signal Srst4 of the black level is obtained, and thus a signal component according to the charges accumulated in the photoelectric conversion unit PDu_Bu is detected. At this time, the accumulation period of time of the photoelectric conversion unit PDu_Bu is TM4. Further, in order to form the potential gradient from the photoelectric conversion unit PDu_Bu to the photoelectric conversion unit PDd_Bd, when the read transistor TGb1 transitions from the off state to the on state, the voltage of the photo gate TPGb1 may be temporarily raised.

Here, in the second read operation, it is possible to read the charges accumulated in the photoelectric conversion unit PDu_Bu in which the leakage current is small after discharging the charges accumulated in the photoelectric conversion unit PDd_Bd in which the leakage current is large, and it is possible to reduce the degradation of an image quality caused by white spots, a leakage current, or the like.

### Fourth Embodiment

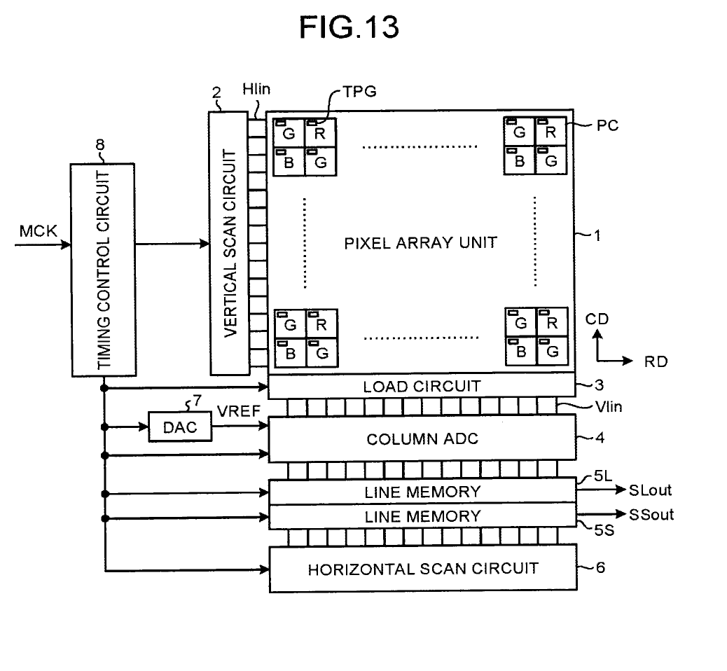

FIG. 13 is a block diagram illustrating a schematic configuration of a solid-state imaging device according to a fourth embodiment.

In FIG. 13, in the solid-state imaging device, line memories 5L and 5S are disposed instead of the line memory 5 of FIG. 1. The pixel PC of the solid-state imaging device may have the configuration of FIG. 8. For example, the accumulation periods of time of the photoelectric conversion units PDd_Grd, PDd_Bd, PDd_Rd, and PDd_Gbd are set to be shorter than the accumulation periods of time of the photoelectric conversion units PDu_Gru, PDu_Bu, PDu_Ru, and PDu_Gbu.

Then, as the vertical scan circuit 2 scans the pixels PC one by one in the vertical direction, the pixels PC are selected in the row direction RD, and signals are read from the photoelectric conversion units PDd_Grd, PDd_Bd, PDd_Rd, and PDd_Gbd. Then, the load circuit 3 performs the source follower operation with the pixels PC in units of columns, and thus the pixel signals read from the photoelectric conversion units PDd_Grd, PDd_Bd, PDd_Rd, and PDd_Gbd are transferred to the column ADC circuit 4 via the vertical signal lines Vlin. Then, the column ADC circuit 4 performs conversion into a digital signal by performing the clock count operation until the signal level and the reset level read from the photoelectric conversion units PDd_Grd, PDd_Bd, PDd_Rd, and PDd_Gbd match the levels of the ramp wave. At this time, as a difference between the signal level and the reset level is obtained, the signal components of the photoelectric conversion units PDd_Grd, PDd_Bd, PDd_Rd, and PDd_Gbd are detected through the CDS and output via the line memory 5S as an output signal SSout.

Further, subsequently to reading of signals from the photoelectric conversion units PDd_Grd, PDd_Bd, PDd_Rd, PDd_Gbd, signals are read from the photoelectric conversion units PDu_Gru, PDu_Bu, PDu_Ru, and PDu_Gbu. Then, the load circuit 3 performs the source follower operation with the pixels PC in units of columns, and thus the pixel signals read from the photoelectric conversion units PDu_Gru, PDu_Bu, PDu_Ru, and PDu_Gbu are transferred to the column ADC circuit 4 via the vertical signal lines Vlin. Then, the column ADC circuit 4 performs conversion into a digital signal by performing the clock count operation until the signal level and the reset level read from the photoelectric conversion units PDu_Gru, PDu_Bu, PDu_Ru, and PDu_Gbu match the levels of the ramp wave. At this time, as a difference between the signal level and the reset level is obtained, the signal components of the photoelectric conversion units PDu_Gru, PDu_Bu, PDu_Ru, and PDu_Gbu are detected through the CDS, and output via the line memory 5L as an output signal SLout.

Here, it is possible to increase the dynamic range without lowering the resolution by setting the accumulation periods of time of the photoelectric conversion units PDd_Grd, PDd_Bd, PDd_Rd, and PDd_Gbd to be shorter than the accumulation periods of time of the photoelectric conversion unit PDu_Gru, PDu_Bu, PDu_Ru, and PDu_Gbu and individually reading the signals from the photoelectric conversion units PDd_Grd, PDd_Bd, PDd_Rd, and PDd_Gbd and the signals from the photoelectric conversion units PDu_Gru, PDu_Bu, PDu_Ru, and PDu_Gbu.

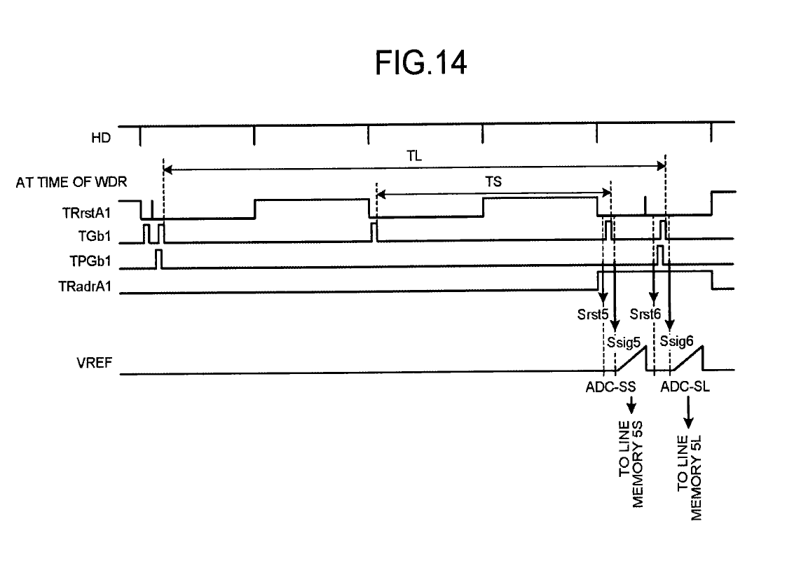

FIG. 14 is a timing chart illustrating voltage waveforms of the respective components when the pixel of FIG. 13 performs the read operation. The example of FIG. 14 illustrates the read operations of the photoelectric conversion units PDd_Bd and PDu_Bu of FIG. 8.

In FIG. 14, in the read operation, the voltage of the photo gate TPGb1 is set to VPG_L during the charge accumulation operation.

Then, in a state in which the voltage of the photo gate TPGb1 is raised, the read transistor TGb1 is turned on, and thus the residual charges of the photoelectric conversion units PDd_Bd and PDu_Bu are discharged to the floating diffusion FDA1. Thereafter, after the voltage of the photo gate TPGb1 is fallen, the read transistor TGb1 is turned off, and thus an operation of accumulating the signal charges in the photoelectric conversion unit PDu_Bu starts. As a result, the accumulation period of time of the photoelectric conversion unit PDu_Bu can be set to TL. Then, as the reset transistor TRrstA1 is turned on, the charges of the floating diffusion FDA1 are discharged, and then the reset transistor TRrstA1 is turned off.

Then, as the read transistor TGb1 is turned on, the charges accumulated in the photoelectric conversion unit PDd_Bd are discharged to the floating diffusion FDA1. Then, as the read transistor TGb1 is turned off, an operation of accumulating the signal charges in the photoelectric conversion unit PDd_Bd starts. As a result, the accumulation period of time of the photoelectric conversion unit PDd_Bd can be set to TS. Thereafter, after the read transistor TGb1 is turned off, the reset transistor TRrstA1 is turned on, and thus the charges of the floating diffusion FDA1 are discharged, and the reset transistor TRrstA1 is turned off.

Then, the row selecting transistor TRadrA1 is turned on when the read transistor TGb1 is in the off state, and thus the amplifying transistor TRampA1 performs the source follower operation, and the voltage according to the charges of the black level of the floating diffusion FDA1 is read out to the vertical signal line Vlin1. Then, a pixel signal Srst5 of the black level is detected based on the voltage of the vertical signal line Vlin1 at this time. Thereafter, as the read transistor TGb1 is turned on, the signal charges of the photoelectric conversion unit PDd_Bd are read out to the floating diffusion FDA1. Then, the amplifying transistor TRampA1 performs the source follower operation, and thus the voltage according to the charges of the signal level of the floating diffusion FDA1 is read out to the vertical signal line Vlin1. Then, a pixel signal Ssig5 of the signal level is detected based on the voltage of the vertical signal line Vlin1 at this time. Then, a difference between the pixel signal Ssig5 of the signal level and the pixel signal Srst5 of the black level is obtained, and thus a signal component according to the charges accumulated in the photoelectric conversion unit PDd_Bd is detected.

Then, in a state in which the read transistor TGb1 is turned off, the reset transistor TRrstA1 is turned on, and thus the charges of the floating diffusion FDA1 are discharged, and then the reset transistor TRrstA1 is turned off.

Then, the amplifying transistor TRampA1 performs the source follower operation when the read transistor TGb1 is in the off state and the row selecting transistor TRadrA1 is in the on state, and thus the voltage according to the charges of the black level of the floating diffusion FDA1 is read out to the vertical signal line Vlin1. Then, a pixel signal Srst6 of the black level is detected based on the voltage of the vertical signal line Vlin1 at this time. Then, after the voltage of the photo gate TPGb1 is raised, the read transistor TGb1 is turned on, and thus the signal charges of the photoelectric conversion unit PDu_Bu are read out to the floating diffusion FDA1. Then, after the voltage of the photo gate TPGb1 is fallen, the read transistor TGb1 is turned off, and the amplifying transistor TRampA1 performs the source follower operation, and thus the voltage according to the charges of the signal level of the floating diffusion FDA1 is read out to the vertical signal line Vlin1. Then, a pixel signal Ssig6 of the signal level is detected based on the voltage of the vertical signal line Vlin1 at this time. Then, a difference between the pixel signal Ssig6 of the signal level and the pixel signal Srst6 of the black level is obtained, and thus a signal component according to the charges accumulated in the photoelectric conversion unit PDu_Bu is detected.

The signal components according to the charges accumulated in the photoelectric conversion units PDd_Bd and PDu_Bu are detected during one horizontal period of time and held in the line memories 5S and 5L, respectively. Then, the signal components held in the line memories 5S and 5L are simultaneously output during next one horizontal period of time, and the output signal SSout is amplified by subsequent signal processing so that the accumulation periods TL and TS of time are equal. At this time, an amplification coefficient is indicated by TL/TS. Then, the output signals SSout and SLout in which the accumulation periods TL and TS of time are made to be equal are combined to be linear with respect to an incident light quantity, and thus the dynamic range is increased.

### Fifth Embodiment

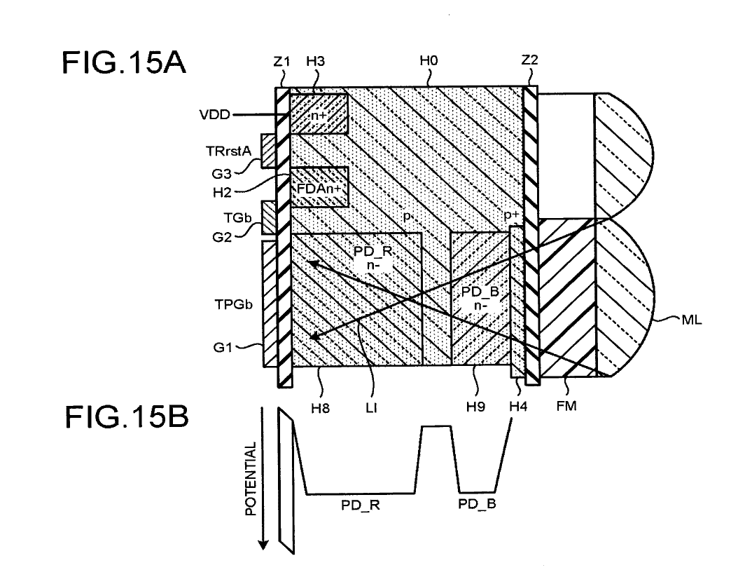

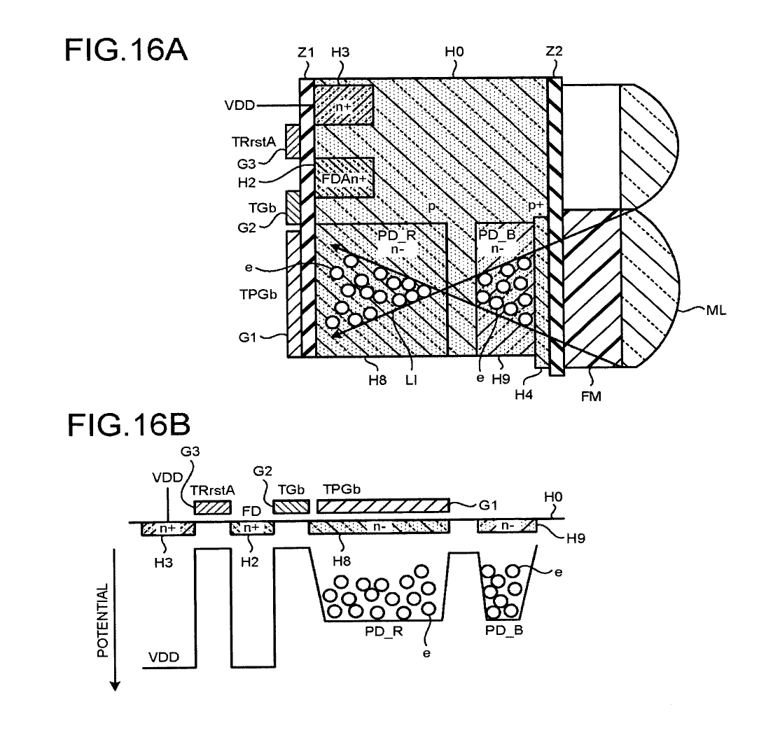

FIG. 15A is a cross-sectional view illustrating an exemplary pixel configuration of a solid-state imaging device according to a fifth embodiment, FIG. 15B is a diagram illustrating a potential distribution in the exemplary configuration of FIG. 15A, FIG. 16A is a cross-sectional view illustrating a charge accumulation state of the configuration of FIG. 15A, and FIG. 16B is a diagram illustrating a potential distribution of the state of FIG. 15A. FIG. 15A and FIG. 16A illustrate a schematic configuration of the blue pixel B of FIG. 1.

In FIG. 15A, in this exemplary configuration, diffusion layers H8 and H9 are disposed in the semiconductor layer H0 instead of the diffusion layer H1 of FIG. 3A. The diffusion layer H8 may configure the photoelectric conversion unit PD_R corresponding to the red pixel R, and the diffusion layer H9 may configure the photoelectric conversion unit PD_B corresponding to the blue pixel B. The diffusion layer H8 is preferably arranged at a position of 2 μm to 3 μm from the light incident plane of the semiconductor layer H0 in order to increase sensitivity to red light. The diffusion layer H9 is preferably arranged at a position of 0.3 μm to 0.5 μm from the light incident plane of the semiconductor layer H0 in order to increase sensitivity to blue light. A magenta filter FM is disposed instead of the blue filter FB. The magenta filter FM may not be disposed. The diffusion layer H8 is arranged at the front surface side of the semiconductor layer H0, and the diffusion layer H9 is arranged at the back surface side of the semiconductor layer H0. The diffusion layers H8 and H9 are arranged to overlap. The diffusion layers H8 and H9 may be set to an n⁻ type.

Among the components of the incident light LI condensed through the micro lens ML, blue light and red light are selected through the magenta filter FM, blue light is subjected to photoelectric conversion by the diffusion layer H9, and red light is subjected to photoelectric conversion by the diffusion layer H8. Then, as illustrated in FIG. 16A, the charges e corresponding to blue light are accumulated in the diffusion layer H8, and the charges e corresponding to red light are accumulated in the diffusion layer H9.

Here, the voltage of the photo gate TPGb can be set so that the potentials of the photoelectric conversion units PD_R and PD_B are equal to each other as illustrated in FIG. 16B. Then, after the charges e are read from the photoelectric conversion unit PD_R, the charges e can be read from the photoelectric conversion unit PD_B. Thus, it is possible to stack the photoelectric conversion units PD_R and PD_B, it is possible to increase the light reception areas of the photoelectric conversion units PD_R and PD_B, and thus it is possible to increase sensitivity to red light and blue light.

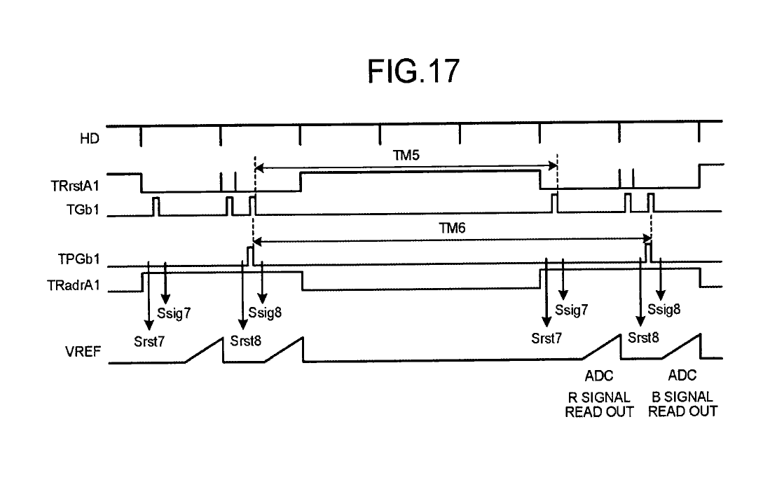

FIG. 17 is a timing chart illustrating voltage waveforms of the respective components when the pixel of FIG. 15A performs the read operation.

In FIG. 17, in the read operation, the voltage of the photo gate TPGb1 is set to VPG_L during the charge accumulation operation.

Then, in a state in which the voltage of the photo gate TPGb1 is raised, the read transistor TGb1 is turned on, and thus the residual charges of the photoelectric conversion units PD_R and PD_B are discharged to the floating diffusion FDA1. Thereafter, after the voltage of the photo gate TPGb1 is fallen, the read transistor TGb1 is turned off, and thus an operation of accumulating the signal charges in the photoelectric conversion units PD_R and PD_B starts. Then, the reset transistor TRrstA1 is turned on, and thus the charges of the floating diffusion FDA1 are discharged, and then the reset transistor TRrstA1 is turned off.

Then, the row selecting transistor TRadrA1 is turned on when the read transistor TGb1 is in the off state, and thus the amplifying transistor TRampA1 performs the source follower operation, and the voltage according to the charges of the black level of the floating diffusion FDA1 is read out to the vertical signal line Vlin1. Then, a pixel signal Srst7 of the black level is detected based on the voltage of the vertical signal line Vlin1 at this time. Thereafter, as the read transistor TGb1 is turned on, the signal charges of the photoelectric conversion unit PD_R are read out to the floating diffusion FDA1. Then, the amplifying transistor TRampA1 performs the source follower operation, and thus the voltage according to the charges of the signal level of the floating diffusion FDA1 is read out to the vertical signal line Vlin1. Then, a pixel signal Ssig7 of the signal level is detected based on the voltage of the vertical signal line Vlin1 at this time. Then, a difference between the pixel signal Ssig7 of the signal level and the pixel signal Srst7 of the black level is obtained, and thus a signal component according to the charges accumulated in the photoelectric conversion unit PD_R is detected. At this time, the accumulation period of time of the photoelectric conversion unit PD_R is TM5.

Then, in a state in which the read transistor TGb1 is turned off, the reset transistor TRrstA1 is turned on, and thus the charges of the floating diffusion FDA1 are discharged, and then the reset transistor TRrstA1 is turned off. Thereafter, as the read transistor TGb1 is turned on, charges of one horizontal period of time accumulated in the photoelectric conversion unit PD_R are discharged to the floating diffusion FDA1. Then, in a state in which the read transistor TGb1 is turned off, the reset transistor TRrstA1 is turned on, and thus the charges of the floating diffusion FDA1 are discharged, and then the reset transistor TRrstA1 is turned off.

Then, the amplifying transistor TRampA1 performs the source follower operation when the read transistor TGb1 is in the off state and the row selecting transistor TRadrA1 is in the on state, and thus the voltage according to the charges of the black level of the floating diffusion FDA1 is read out to the vertical signal line Vlin1. Then, a pixel signal Srst8 of the black level is detected based on the voltage of the vertical signal line Vlin1 at this time. Then, after the voltage of the photo gate TPGb1 is raised, the read transistor TGb1 is turned on, and thus the signal charges of the photoelectric conversion unit PD_B are read out to the floating diffusion FDA1. Then, after the voltage of the photo gate TPGb1 is fallen, the read transistor TGb1 is turned off, and the amplifying transistor TRampA1 performs the source follower operation, and thus the voltage according to the charges of the signal level of the floating diffusion FDA1 is read out to the vertical signal line Vlin1. Then, a pixel signal Ssig8 of the signal level is detected based on the voltage of the vertical signal line Vlin1 at this time. Then, a difference between the pixel signal Ssig8 of the signal level and the pixel signal Srst8 of the black level is obtained, and thus a signal component according to the charges accumulated in the photoelectric conversion unit PD_B is detected. At this time, the accumulation period of time of the photoelectric conversion unit PD_B is TM6.

### Sixth Embodiment

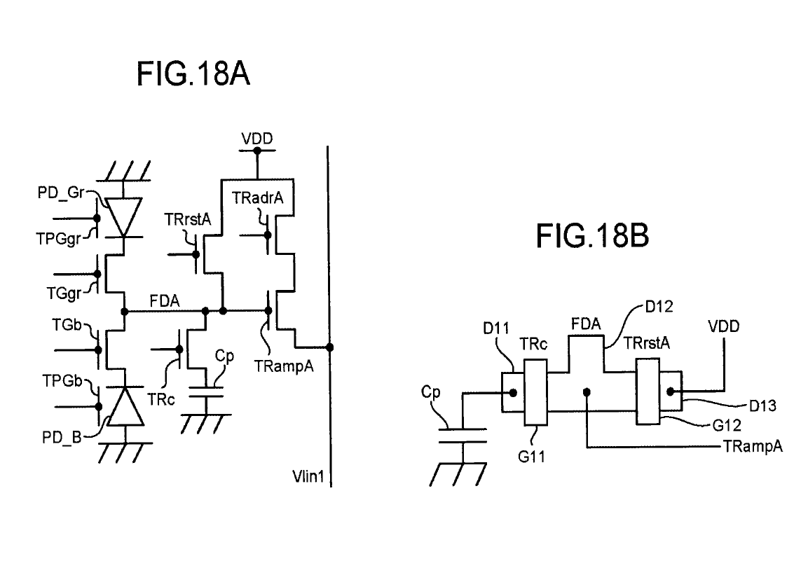

FIG. 18A is a circuit diagram illustrating an exemplary configuration of a switching transistor applied to a solid-state imaging device according to a sixth embodiment, and FIG. 18B is a plane view illustrating an exemplary layout configuration of the switching transistor of FIG. 18A.

In FIG. 18A, in the solid-state imaging device, a capacitor Cp is added to the floating diffusion FDA of FIG. 2 via a coupling transistor TRc. The coupling transistor TRc is provided with a gate electrode G11, and the reset transistor TRrstA is provided with a gate electrode G12 as illustrated in FIG. 18B. A diffusion layer D12 is formed between the gate electrodes G11 and G12. A diffusion layer D11 is formed at a side of the gate electrode G11 opposite to the diffusion layer D12, and a diffusion layer D13 is formed at a side of the gate electrode G12 opposite to the diffusion layer D12. The diffusion layer D11 is connected with the capacitor Cp.

Here, the capacitor Cp can be added to the floating diffusion FDA by turning on the coupling transistor TRc. Thus, it is possible to increase the saturation electron number of the floating diffusion FDA and decrease the conversion gain.

### Seventh Embodiment

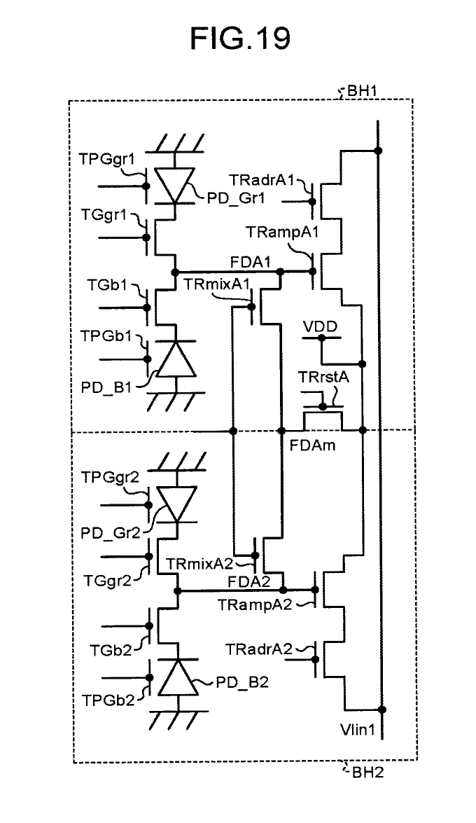

FIG. 19 is a circuit diagram illustrating an exemplary pixel configuration of 1×4 pixels in a 2-pixel 1-cell configuration of a solid-state imaging device according to a seventh embodiment. The example of FIG. 19 illustrates only the blue pixel B and the green pixel Gr of FIG. 6. The red pixel R and the green pixel Gb of FIG. 6 can be similarly configured.

In FIG. 19, in the solid-state imaging device, switching transistors TRmixA1 and TRmixA2 are disposed instead of the switching transistor TRmixA of FIG. 6. Further, a reset transistor TRrstA is disposed instead of the reset transistors TRrstA1 and TRrstA2 of FIG. 6.

The switching transistors TRmixA1 and TRmixA2 are connected with each other in series, and the serial circuit is connected between the floating diffusions FDA1 and FDA2. The gates of the switching transistors TRmixA1 and TRmixA2 are mutually connected with each other. The reset transistor TRrstA is connected between the connection point of the switching transistors TRmixA1 and TRmixA2 and the power potential VDD. The floating diffusion FDAm is formed at the connection point of the switching transistors TRmixA1 and TRmixA2. The switching transistor TRmixA1 can be arranged near the floating diffusion FDA1. The switching transistor TRmixA2 can be arranged near the floating diffusion FDA2.

The switching transistors TRmixA1 and TRmixA2 can operate similarly to the switching transistor TRmixA, and the reset transistor TRrstA can operate similarly to the reset transistors TRrstA1 and TRrstA2.

Here, as the switching transistors TRmixA1 and TRmixA2 are arranged near the floating diffusions FDA1 and FDA2, it is possible to reduce an interconnection capacity added to the floating diffusions FDA1 and FDA2 during the second read operation of FIG. 7B, and it is possible to increase the conversion gain. Further, the two reset transistors TRrstA1 and TRrstA2 of FIG. 6 can be reduced to one transistor. Similarly, the two reset transistors TRrstB1 and TRrstB2 can be reduced to one transistor.

### Eighth Embodiment

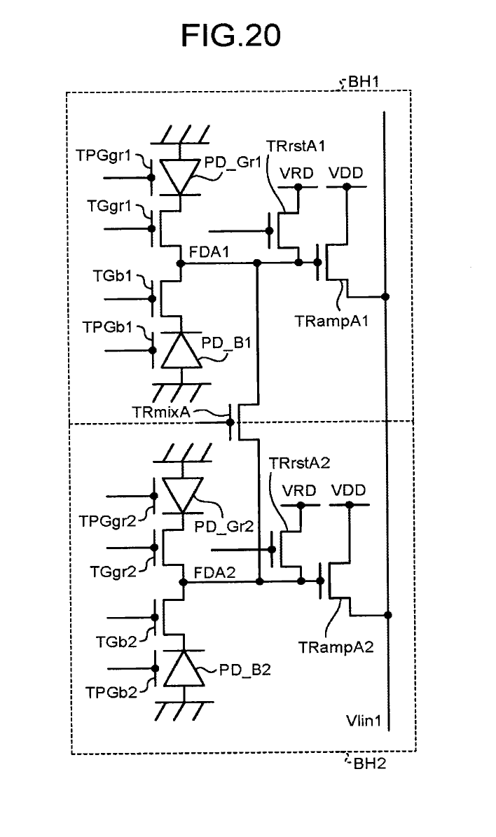

FIG. 20 is a circuit diagram illustrating an exemplary pixel configuration of 1×4 pixels in a 2-pixel 1-cell configuration of a solid-state imaging device according to an eighth embodiment. The example of FIG. 20 illustrates only the blue pixel B and the green pixel Gr of FIG. 6. The red pixel R and the green pixel Gb of FIG. 6 can be similarly configured.

In FIG. 20, in the solid-state imaging device, the row selecting transistors TRadrA1 and TRadrA2 of FIG. 6 are not provided. Further, in the solid-state imaging device, the floating diffusion FDA1 is connected to a power potential VRD via the reset transistor TRrstA1, and the floating diffusion FDA2 is connected to the power potential VRD via the reset transistor TRrstA2.

Here, in the configuration of FIG. 6, as the row selecting transistors TRadrA1 and TRadrA2 is turned off, non-selection rows are set. On the other hand, in the configuration of FIG. 20, as the power potential VRD is fallen when the reset transistors TRrstA1 and TRrstA2 are in the on state, and the amplifying transistors TRampA1 and TRampA2 are turned off, non-selection rows are set. The remaining components can operate similarly to those of FIG. 6.

Thus, even when the row selecting transistors TRadrA1 and TRadrA2 are removed, it is possible to connect or separate the floating diffusions FDA1 and FDA2 to or from each other through the switching transistor TRmixA.

### Ninth Embodiment

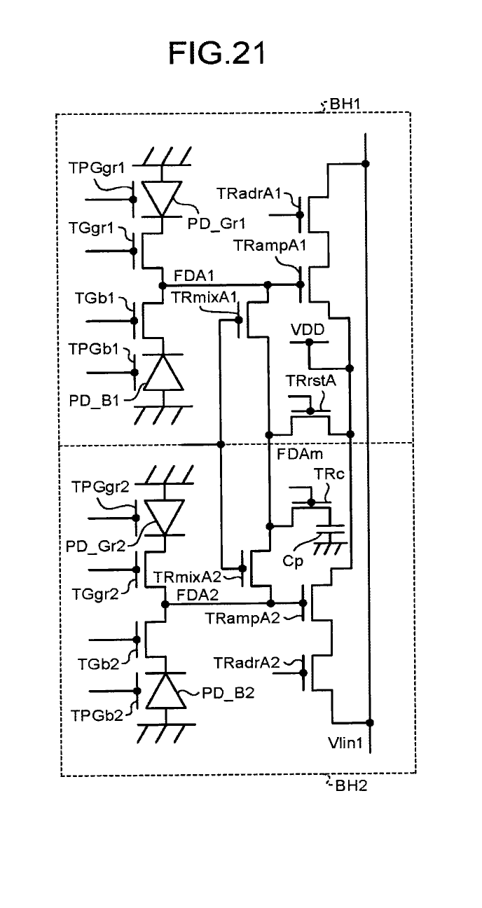

FIG. 21 is a circuit diagram illustrating an exemplary pixel configuration of 1×4 pixels in a 2-pixel 1-cell configuration of a solid-state imaging device according to a ninth embodiment.

In FIG. 21, in the solid-state imaging device, a coupling transistor TRc and a capacitor Cp are added to the configuration of FIG. 19. The capacitor Cp is connected to a connection point FDAm of the switching transistors TRmixA1 and TRmixA2 via the coupling transistor TRc.

Here, it is possible to add the capacitor Cp to the floating diffusions FDA1 and FDA2 by turning on the coupling transistor TRc when the switching transistors TRmixA1 and TRmixA2 are in the on state. Thus, it is possible to increase the saturation electron numbers of the floating diffusions FDA1 and FDA2, and it is possible to decrease the conversion gain.

### Tenth Embodiment

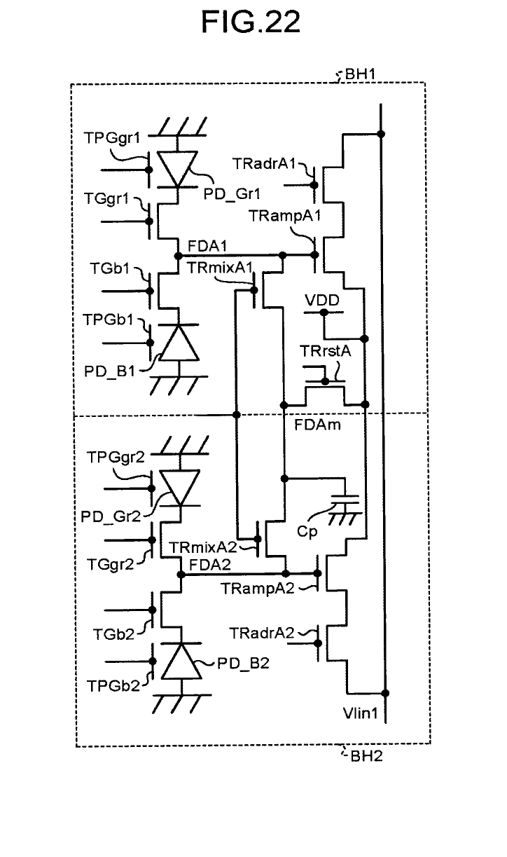

FIG. 22 is a circuit diagram illustrating an exemplary pixel configuration of 1×4 pixels in a 2-pixel 1-cell configuration of a solid-state imaging device according to a tenth embodiment.

In FIG. 22, in the solid-state imaging device, the coupling transistor TRc is removed from the configuration of FIG. 21. The capacitor Cp is connected directly to the connection point of the switching transistors TRmixA1 and TRmixA2.

Here, it is possible to add the capacitor Cp to the floating diffusions FDA1 and FDA2 by turning on the switching transistors TRmixA1 and TRmixA2. Thus, it is possible to increase the saturation electron numbers of the floating diffusions FDA1 and FDA2, and it is possible to decrease the conversion gain.

### Eleventh Embodiment

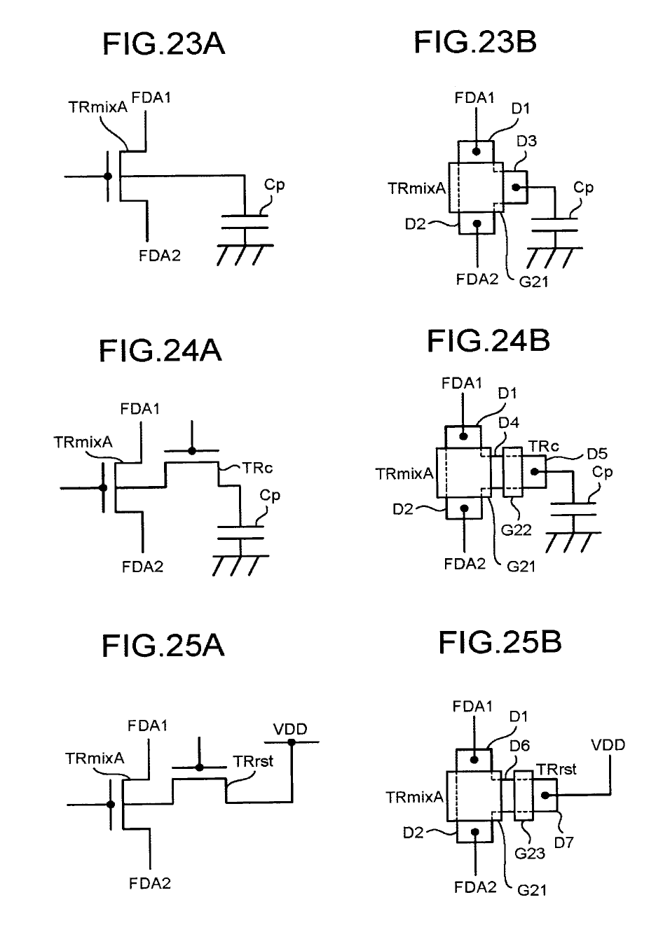

FIG. 23A is a circuit diagram illustrating an exemplary configuration of a switching transistor applied to a solid-state imaging device according to an eleventh embodiment, and FIG. 23B is a plane view illustrating an exemplary layout configuration of the switching transistor of FIG. 23A.

In FIG. 23A, in the solid-state imaging device, the capacitor Cp is added to a channel area of the switching transistor TRmixA of FIG. 6. Further, as illustrated in FIG. 23B, the switching transistor TRmixA is provided with the gate electrode G21, and the channel area is formed below the gate electrode G21. Diffusion layers D1 and D2 are formed at both sides of the channel area. A diffusion layer D3 is formed at the side of the channel area, and the capacitor Cp is connected to the diffusion layer D3.

Here, it is possible to add the capacitor Cp to the floating diffusions FDA1 and FDA2 by turning on the switching transistor TRmixA. Thus, it is possible to increase the saturation electron numbers of the floating diffusions FDA1 and FDA2, and it is possible to decrease the conversion gain. As the diffusion layer D3 connected with the capacitor Cp is arranged at the side of the channel area, it is possible to suppress an increase in a layout area.

### Twelfth Embodiment

FIG. 24A is a circuit diagram illustrating an exemplary configuration of a switching transistor applied to a solid-state imaging device according to a twelfth embodiment, and FIG. 24B is a plane view illustrating an exemplary layout configuration of the switching transistor of FIG. 24A.

In FIG. 24A, in the solid-state imaging device, the capacitor Cp is added to the channel area of the switching transistor TRmixA of FIG. 23A via the coupling transistor TRc. Further, as illustrated in FIG. 24B, the coupling transistor TRc is provided with a gate electrode G22. Diffusion layers D4 and D5 are formed at both sides of the channel area below the gate electrode G22. Here, the diffusion layer D4 is arranged at the side of the channel area of the switching transistor TRmixA. The capacitor Cp is connected to the diffusion layer D5.

Here, it is possible to add the capacitor Cp to the floating diffusions FDA1 and FDA2 by turning on the coupling transistor TRc when the switching transistor TRmixA is in the on state. Thus, it is possible to increase the saturation electron numbers of the voltage converting units of the floating diffusions FDA1 and FDA2, and it is possible to decrease the conversion gain. Further, as the diffusion layer D4 of the coupling transistor TRc is arranged at the side of the channel area of the switching transistor TRmixA, an interconnection for connecting the switching transistor TRmixA with the coupling transistor TRc is unnecessary, and it is possible to suppress an increase in a layout area.

### Thirteenth Embodiment

FIG. 25A is a circuit diagram illustrating an exemplary configuration of a switching transistor applied to a solid-state imaging device according to a thirteenth embodiment, and FIG. 25B is a plane view illustrating an exemplary layout configuration of the switching transistor of FIG. 25A.

In FIG. 25A, in the solid-state imaging device, the reset transistor TRrst is disposed instead of the reset transistors TRrstA1 and TRrstA2 of FIG. 6. Here, the channel area of the switching transistor TRmixA is connected to the power potential VDD via the reset transistor TRrst. Further, as illustrated in FIG. 25B, the reset transistor TRrst is provided with a gate electrode G23. Diffusion layers D6 and D7 are formed at both sides of the channel area below the gate electrode G23. Here, the diffusion layer D6 is arranged at the side of the channel area of the switching transistor TRmixA. The diffusion layer D7 is connected with the power potential VDD.

Here, it is possible to reset the floating diffusions FDA1 and FDA2 by turning on the reset transistor TRrst when the switching transistor TRmixA is in the on state. Further, as the diffusion layer D6 of the reset transistor TRrst is arranged at the side of the channel area of the switching transistor TRmixA, the reset transistor TRrst can be shared by the floating diffusions FDA1 and FDA2. Thus, it is unnecessary to dispose the reset transistors TRrstA1 and TRrstA2 of FIG. 2 for the floating diffusions FDA1 and FDA2, respectively, and thus it is possible to reduce the number of reset transistors.

### Fourteenth Embodiment

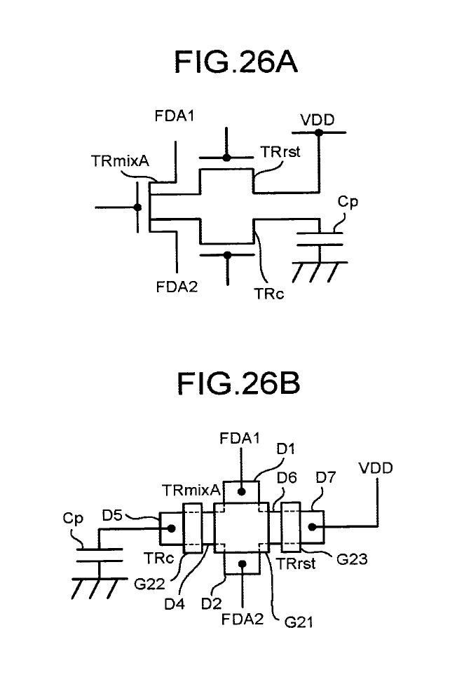

FIG. 26A is a circuit diagram illustrating an exemplary configuration of a switching transistor applied to a solid-state imaging device according to a fourteenth embodiment, and FIG. 26B is a plane view illustrating an exemplary layout configuration of the switching transistor of FIG. 26A.

In FIG. 26A, in the solid-state imaging device, the capacitor Cp is added to the channel area of the switching transistor TRmixA of FIG. 25A via the coupling transistor TRc. The coupling transistor TRc has a similar configuration to those of FIGS. 24A and 24B. Here, the diffusion layer D4 of the coupling transistor TRc and the diffusion layer D6 of the reset transistor TRrst can be arranged at the sides of the channel area below the gate electrode G21 to face each other with the gate electrode G21 interposed therebetween.

Here, as the diffusion layer D4 of the coupling transistor TRc is arranged at the side of the channel area of the switching transistor TRmixA, an interconnection for connecting the switching transistor TRmixA with the coupling transistor TRc is unnecessary, and it is possible to suppress an increase in a layout area. Further, as the diffusion layer D6 of the reset transistor TRrst is arranged at the side of the channel area of the switching transistor TRmixA, it is unnecessary to dispose the reset transistors TRrstA1 and TRrstA2 of FIG. 6 for the floating diffusions FDA1 and FDA2, respectively, and thus it is possible to reduce the number of reset transistors.

### Fifteenth Embodiment

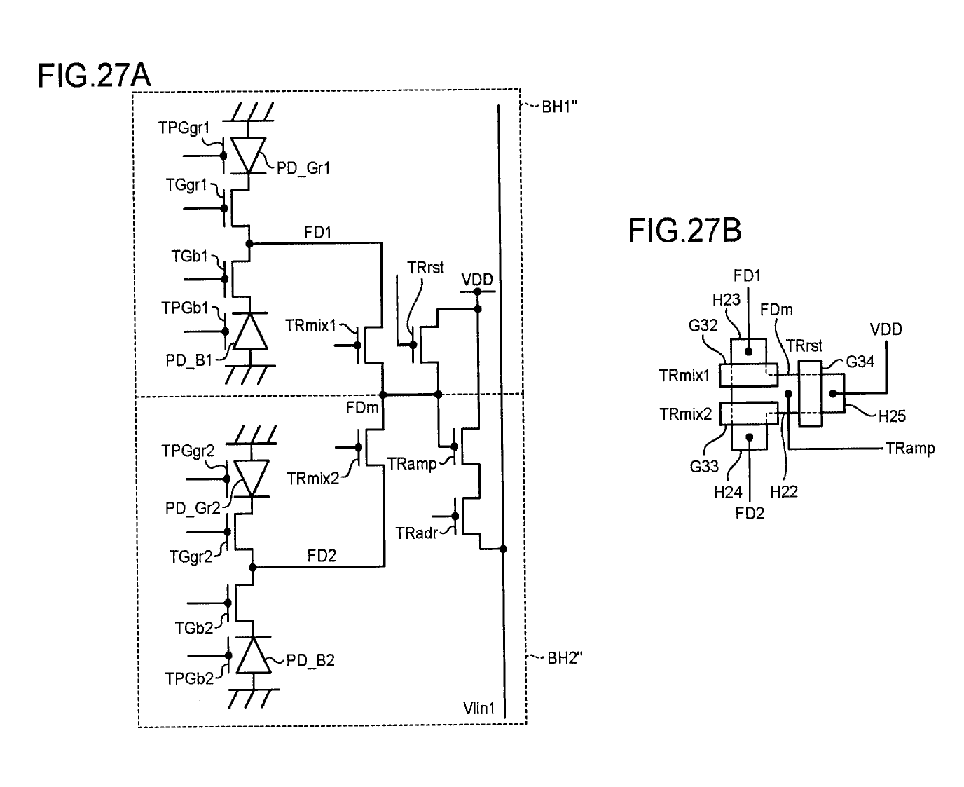

FIG. 27A is a circuit diagram illustrating an exemplary pixel configuration of 1×4 pixels in a 2-pixel 1-cell configuration of a solid-state imaging device according to a fifteenth embodiment, and FIG. 27B is a plane view illustrating an exemplary layout configuration of the division transistor of FIG. 27A. The example of FIG. 27A illustrates only the blue pixel B and the green pixel Gr of FIG. 1. The red pixel R and the green pixel Gb of FIG. 1 can be similarly configured.

In FIG. 27A, in the solid-state imaging device, division transistors TRmix1 and TRmix2 that divide a voltage converting unit that converts charges generated by the pixels PC into a voltage into a first voltage converting unit and a second voltage converting unit that are different in potential from each other are disposed. The division transistors TRmix1 and TRmix2 are disposed for each pixel PC. Here, since the potential of the first voltage converting unit is different from the potential of the second voltage converting unit, it is possible to divide the capacity of the first voltage converting unit and the capacity of the second voltage converting unit. At the time of low luminance shooting, it is possible to increase the conversion gain by dividing the voltage converting unit through the division transistors TRmix1 and TRmix2. At the time of high luminance shooting, it is possible to increase the saturation electron number by causing the voltage converting unit not to be divided through the division transistors TRmix1 and TRmix2. The division transistors TRmix1 and TRmix2 may be automatically switched based on an external luminance measurement result or may be arbitrarily switched by the user.

Here, when the capacity of the voltage converting unit is divided, it is possible to reduce the capacity of the voltage converting unit that converts charges accumulated in the pixel PC into a voltage to be smaller than when the capacity of the voltage converting unit is not divided, and thus it is possible to improve an SN ratio. Meanwhile, when the capacity of the voltage converting unit is not divided, it is possible to increase the saturation electron number of the voltage converting unit to be larger than when the capacity of the voltage converting unit is divided, and thus it is possible to increase the dynamic range.

Next, a connection relation of the division transistors TRmix1 and TRmix2 will be specifically described. Bayer arrays BH1″ and BH2″ are arranged to be adjacent to each other in the column direction CD.

In the Bayer array BH1″, a photoelectric conversion unit PD_Gr1 is disposed for the green pixel Gr, and a photoelectric conversion unit PD_B1 is disposed for the blue pixel B. In the Bayer array BH2″, a photoelectric conversion unit PD_Gr2 is disposed for the green pixel Gr, a photoelectric conversion unit PD_B2 is disposed for the blue pixel B. Further, in the Bayer array BH1″, read transistors TGgr1 and TGb1 and a division transistor TRmix1 are disposed, and in the Bayer array BH2″, read transistors TGgr2 and TGb2 and a division transistor TRmix2 are disposed. A row selecting transistor TRadr, an amplifying transistor TRamp, and a reset transistor TRrst are disposed to be common to the Bayer arrays BH1″ and BH2″. A floating diffusion FD1 is formed at connection point of the read transistors TGgr1 and TGb1 as a first voltage converting unit, a floating diffusion FDm is formed at a connection point of the amplifying transistor TRamp and the reset transistor TRrst as a second voltage converting unit, and a floating diffusion FD2 is formed at a connection point of the read transistors TGgr2 and TGb2 as a third voltage converting unit.

Then, the photoelectric conversion unit PDGrl is connected to the floating diffusion FD1 via the read transistor TGgr1, and the photoelectric conversion unit PD_B1 is connected to the floating diffusion FD1 via the read transistor TGb1. The photoelectric conversion unit PD_Gr2 is connected to the floating diffusion FD2 via the read transistor TGgr2, and the photoelectric conversion unit PD_B2 is connected to the floating diffusion FD2 via the read transistor TGb2.

A gate of the amplifying transistor TRamp is connected to the floating diffusion FDm, a source of the amplifying transistor TRamp is connected to the vertical signal line Vlin1 via the row selecting transistor TRadr, and a drain of the amplifying transistor TRamp is connected to the power potential VDD. The floating diffusion FDm is connected to the power potential VDD via the reset transistor TRrst.

The division transistor TRmix1 is connected between the floating diffusions FD1 and FDm, and the division transistor TRmix2 is connected between the floating diffusions FD2 and FDm.

In FIG. 27B, the division transistor TRmix1 is provided with a gate electrode G32, the division transistor TRmix2 is provided with a gate electrode G33, and the reset transistor TRrst is provided with a gate electrode G34. A diffusion layer H22 is formed among the gate electrodes G32 to G34, a diffusion layer H23 is formed at a side of the gate electrode G32 opposite to the diffusion layer H22, a diffusion layer H24 is formed at a side of the gate electrode G33 opposite to the diffusion layer H22, and a diffusion layer H25 is formed at a side of the gate electrode G34 opposite to the diffusion layer H22. As a result, the division transistors TRmix1 and TRmix2 can be arranged to be adjacent to each other, and the capacity of the floating diffusion FDm can be reduced, and thus the conversion gain can be improved.

### Sixteenth Embodiment

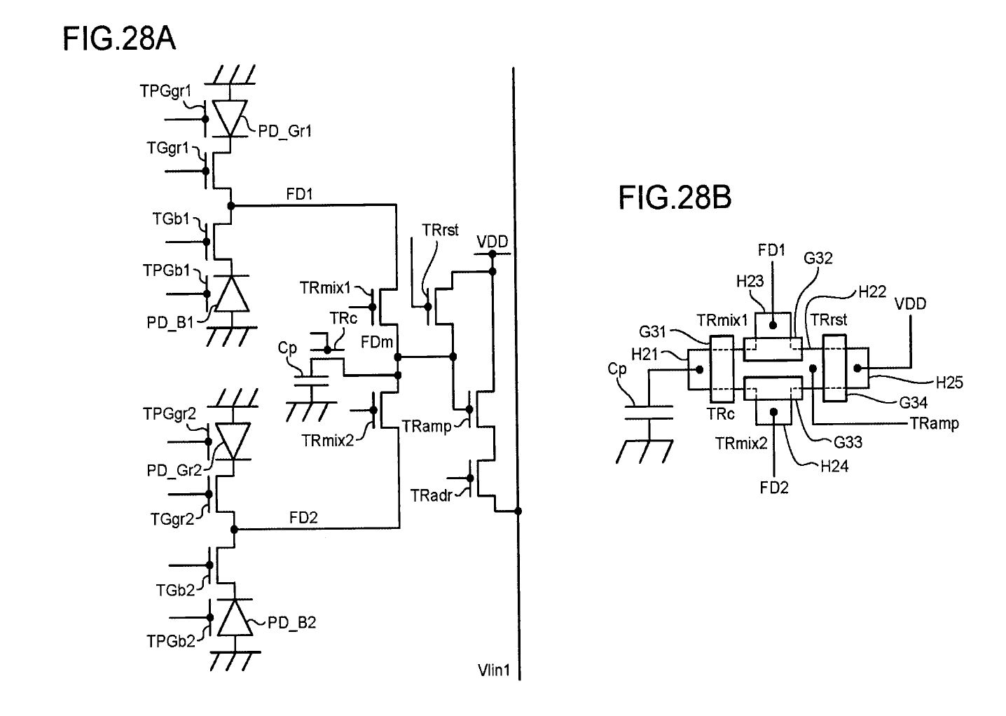

FIG. 28A is a circuit diagram illustrating an exemplary pixel configuration of 1×4 pixels in a 2-pixel 1-cell configuration of a solid-state imaging device according to a sixteenth embodiment, and FIG. 28B is a plane view illustrating an exemplary layout configuration of the division transistor of FIG. 28A.

In FIG. 28A, in the solid-state imaging device, a capacitor Cp is added to the floating diffusion FDm of FIG. 27A via a coupling transistor TRc. Further, as illustrated in FIG. 28B, the coupling transistor TRc is provided with a gate electrode G31. A diffusion layer H22 is formed among the gate electrodes G31 to G34, and a diffusion layer H21 is formed at a side of the gate electrode G31 opposite to the diffusion layer H22. The capacitor Cp is connected to the diffusion layer H21.

Here, it is possible to add the capacitor Cp to the floating diffusion FDm by turning on the coupling transistor TRc, and thus it is possible to increase the saturation electron number. Further, as the gate electrode G31 is arranged to be adjacent to the floating diffusion FDm, an interconnection for connecting the floating diffusion FDm with the coupling transistor TRc is unnecessary, and thus it is possible to suppress an increase in a layout area.

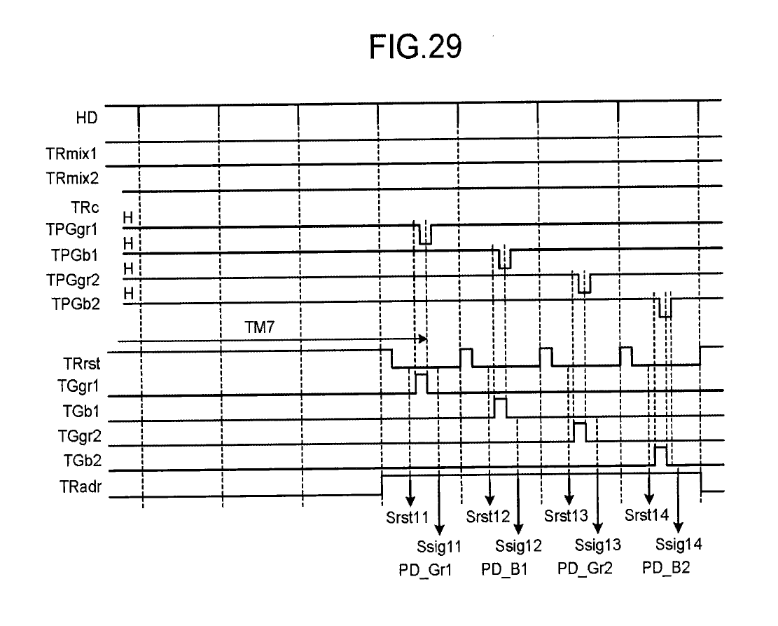

FIG. 29 is a timing chart illustrating voltage waveforms of the respective components when the pixel of FIGS. 28A and 28B performs the first read operation.

In FIG. 29, in the first read operation, the division transistors TRmix1 and TRmix2 are turned on, and thus the capacities of the floating diffusions FD1, FD2, and FDm are combined with each other. Further, as potentials of the photo gates TPGgr1, TPGb1, TPGgr2, and TPGb2 are set to a high level H, potentials of the photoelectric conversion units PD_Gr1, PD_B1, PD_Gr2, and PD_B2 are set to be deep. Further, as the coupling transistor TRc is turned on, the capacitor Cp is added to the floating diffusion FDm.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst11 of the floating diffusions FD1, FD2, and FDm is applied to a gate of the amplifying transistor TRamp, the voltage of the vertical signal line Vlin1 follows a gate voltage of the amplifying transistor TRamp, and thus the pixel signal of the reset level Srst11 is output to the column ADC circuit 4 via the vertical signal line Vlin1.

Then, when the read transistor TGgr1 is turned on, the charges e accumulated in the photoelectric conversion unit PD_Gr1 are transferred to the floating diffusions FDA1, FDA2, and FDAm. Then, as a voltage according to a signal level Ssig11 of the floating diffusions FDA1, FDA2, and FDAm is applied to the gate of the amplifying transistor TRamp, the voltage of the vertical signal line Vlin1 follows the gate voltage of the amplifying transistor TRamp, and thus the pixel signal of the signal level Ssig11 is output to the column ADC circuit 4 via the vertical signal line Vlin1. Then, a difference between the pixel signal of the signal level Ssig11 and the pixel signal of the reset level Srst11 is obtained, and thus a signal component according to the charges accumulated in the photoelectric conversion unit PD_Gr1 is detected. At this time, the accumulation period of time of the photoelectric conversion unit PD_Gr1 is TM7. Further, after the read transistor TGgr1 is turned on, the potential of the photo gate TPGgr1 may be fallen, and after the read transistor TGgr1 is turned off, the potential of the photo gate TPGgr1 may be raised. Here, after the read transistor TGgr1 is turned on, the potential of the photo gate TPGgr1 is fallen, and thus it is possible to form the potential gradient from the photoelectric conversion unit PD_Gr1 to the floating diffusions FDA1, FDA2, and FDAm, and it is possible to efficiently transfer the charges from the photoelectric conversion unit PD_Gr1 to the floating diffusions FDA1, FDA2, and FDAm.

After the pixel signal of the signal level Ssig11 is output to the vertical signal line Vlin1, the reset transistor TRrst is turned on, and thus the charges of the floating diffusions FDA1, FDA2, and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage of a reset level Srst12 of the floating diffusions FD1, FD2, and FDm is applied to the gate of the amplifying transistor TRamp, and the voltage of the vertical signal line Vlin1 follows the gate voltage of the amplifying transistor TRamp, the pixel signal of the reset level Srst12 is output to the column ADC circuit 4 via the vertical signal line Vlin1.

Then, when the read transistor TGb1 is turned on, the charges e accumulated in the photoelectric conversion unit PD_B1 are transferred to the floating diffusions FDA1, FDA2, and FDAm. Then, as a voltage according to a signal level Ssig12 of the floating diffusions FDA1, FDA2, and FDAm is applied to the gate of the amplifying transistor TRampA, the voltage of the vertical signal line Vlin1 follows the gate voltage of the amplifying transistor TRamp, and thus the pixel signal of the signal level Ssig12 is output to the column ADC circuit 4 via the vertical signal line Vlin1. Then, a difference between the pixel signal of the signal level Ssig12 and the pixel signal of the reset level Srst12 is obtained, and a signal component according to the charges accumulated in the photoelectric conversion unit PD_B1 is detected. Further, after the read transistor TGb1 is turned on, the potential of the photo gate TPGb1 may be fallen, and after the read transistor TGb1 is turned off, the potential of the photo gate TPGb1 may be raised.

After the pixel signal of the signal level Ssig12 is output to the vertical signal line Vlin1, the reset transistor TRrst is turned on, and thus the charges of the floating diffusions FDA1, FDA2, and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst13 of the floating diffusions FD1, FD2, and FDm is applied to the gate of the amplifying transistor TRamp, the voltage of the vertical signal line Vlin1 follows the gate voltage of the amplifying transistor TRamp, and thus the pixel signal of the reset level Srst13 is output to the column ADC circuit 4 via the vertical signal line Vlin1.

Then, when the read transistor TGgr2 is turned on, the charges e accumulated in the photoelectric conversion unit PD_Gr2 are transferred to the floating diffusions FDA1, FDA2, and FDAm. Then, as a voltage according to a signal level Ssig13 of the floating diffusions FDA1, FDA2, and FDAm is applied to the gate of the amplifying transistor TRamp, the voltage of the vertical signal line Vlin1 follows the gate voltage of the amplifying transistor TRamp, and thus the pixel signal of the signal level Ssig13 is output to the column ADC circuit 4 via the vertical signal line Vlin1. Then, a difference between the pixel signal of the signal level Ssig13 and the pixel signal of the reset level Srst13 is obtained, and thus a signal component according to the charges accumulated in the photoelectric conversion unit PD_Gr2 is detected. Further, after the read transistor TGgr2 is turned on, the potential of the photo gate TPGgr2 may be fallen, and after the read transistor TGgr2 is turned off, the potential of the photo gate TPGgr2 may be raised.

After the pixel signal of the signal level Ssig13 is output to the vertical signal line Vlin1, the reset transistor TRrst is turned on, and thus the charges of the floating diffusions FDA1, FDA2, and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst14 of the floating diffusions FD1, FD2, and FDm is applied to the gate of the amplifying transistor TRamp, the voltage of the vertical signal line Vlin1 follows the gate voltage of the amplifying transistor TRamp, and thus the pixel signal of the reset level Srst14 is output to the column ADC circuit 4 via the vertical signal line Vlin1.

Then, when the read transistor TGb2 is turned on, the charges e accumulated in the photoelectric conversion unit PD_B2 are transferred to the floating diffusions FDA1, FDA2, and FDAm. Then, as a voltage according to a signal level Ssig14 of the floating diffusions FDA1, FDA2, and FDAm is applied to the gate of the amplifying transistor TRampA, the voltage of the vertical signal line Vlin1 follows the gate voltage of the amplifying transistor TRamp, and thus the pixel signal of the signal level Ssig14 is output to the column ADC circuit 4 via the vertical signal line Vlin1. Then, a difference between the pixel signal of the signal level Ssig14 and the pixel signal of the reset level Srst14 is obtained, a signal component according to the charges accumulated in the photoelectric conversion unit PD_B2 is detected. Further, after the read transistor TGb2 is turned on, the potential of the photo gate TPGb2 may be fallen, and after the read transistor TGb2 is turned off, the potential of the photo gate TPGb2 may be raised.

Here, as the capacitor Cp is added to the floating diffusion FDm while combining the capacities of the floating diffusions FD1, FD2, and FDm, and the potentials of the floating diffusions FD1, FD2, and FDm are caused to be deep, it is possible to increase the saturation electron numbers of the floating diffusions FD1, FD2, and FDm and the photoelectric conversion units PD_Gr1, PD_B1, PD_Gr2, and PD_B2, and it is possible to cope with an increase in the incident light quantity.

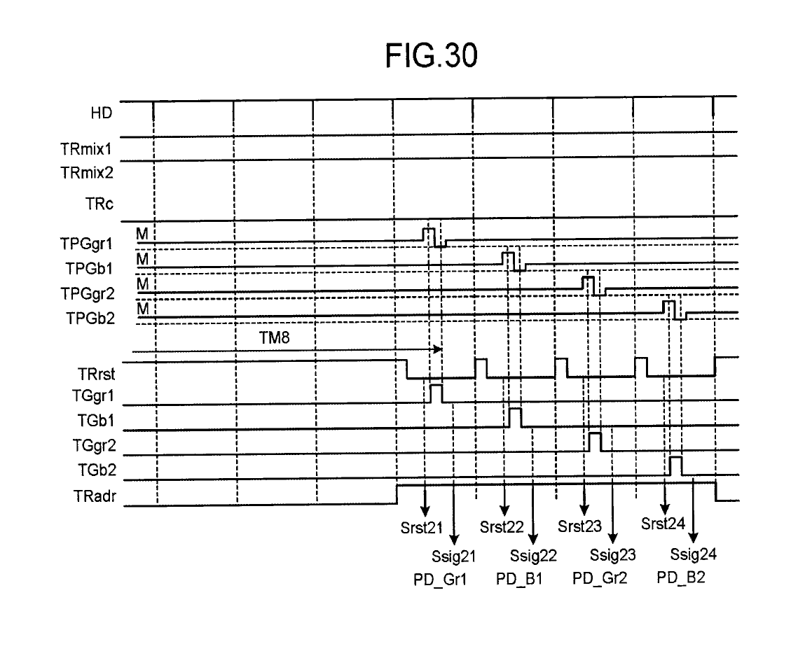

FIG. 30 is a timing chart illustrating voltage waveforms of the respective components when the pixel of FIGS. 28A and 28B performs the second read operation.

In FIG. 30, in the second read operation, as the division transistors TRmix1 and TRmix2 are turned on, the capacities of the floating diffusions FD1, FD2, and FDm are combined with each other. Further, as the potentials of the photo gate TPGgr1, TPGb1, TPGgr2, and TPGb2 are set to an intermediate potential M between the low level LO and the high level HI, the potentials of the photoelectric conversion units PD_Gr1, PD_B1, PD_Gr2, and PD_B2 are set to an intermediate level. The intermediate potential M may be set to 0 V to 2 V. Further, as the coupling transistor TRc is turned off, the capacitor Cp is separated from the floating diffusion FDm.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst21 of the floating diffusions FD1, FD2, and FDm is applied to the gate of the amplifying transistor TRamp, the voltage of the vertical signal line Vlin1 follows the gate voltage of the amplifying transistor TRamp, and thus the pixel signal of the reset level Srst21 is output to the column ADC circuit 4 via the vertical signal line Vlin1.

Then, when the read transistor TGgr1 is turned on, the charges e accumulated in the photoelectric conversion unit PD_Gr1 are transferred to the floating diffusions FDA1, FDA2, and FDAm. Then, as a voltage according to a signal level Ssig21 of the floating diffusions FDA1, FDA2, and FDAm is applied to the gate of the amplifying transistor TRamp, and the voltage of the vertical signal line Vlin1 follows the gate voltage of the amplifying transistor TRamp, and thus the pixel signal of the signal level Ssig21 is output to the column ADC circuit 4 via the vertical signal line Vlin1. Then, a difference between the pixel signal of the signal level Ssig21 and the pixel signal of the reset level Srst21 is obtained, and thus a signal component according to the charges accumulated in the photoelectric conversion unit PD_Gr1 is detected. At this time, the accumulation period of time of the photoelectric conversion unit PD_Gr1 is TMB. Further, the potential of the photo gate TPGgr1 may be raised before the read transistor TGgr1 is turned on, the potential of the photo gate TPGgr1 may be fallen after the read transistor TGgr1 is turned on, and the potential of the photo gate TPGgr1 may be returned to the intermediate level after the read transistor TGgr1 is turned off. Here, as the potential of the photo gate TPGgr1 is raised before the read transistor TGgr1 is turned on, it is possible to form the potential gradient in the depth direction of the photoelectric conversion unit PD_Gr1, and it is possible to efficiently transfer the charges from the bottom of the photoelectric conversion unit PD_Gr1 to the front surface side. Further, as the potential of the photo gate TPGgr1 is fallen after the read transistor TGgr1 is turned on, it is possible to form the potential gradient from the photoelectric conversion unit PD_Gr1 to the floating diffusions FDA1, FDA2, and FDAm, and it is possible to efficiently transfer the charges from the photoelectric conversion unit PD_Gr1 to the floating diffusions FDA1, FDA2, and FDAm.

After the pixel signal of the signal level Ssig21 is output to the vertical signal line Vlin1, the reset transistor TRrst is turned on, and thus the charges of the floating diffusions FDA1, FDA2, and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst22 of the floating diffusions FD1, FD2, and FDm is applied to the gate of the amplifying transistor TRamp, the voltage of the vertical signal line Vlin1 follows the gate voltage of the amplifying transistor TRamp, and thus the pixel signal of the reset level Srst22 is output to the column ADC circuit 4 via the vertical signal line Vlin1.

Then, when the read transistor TGb1 is turned on, the charges e accumulated in the photoelectric conversion unit PD_B1 are transferred to the floating diffusions FDA1, FDA2, and FDAm. Then, as a voltage according to a signal level Ssig22 of the floating diffusions FDA1, FDA2, and FDAm is applied to the gate of the amplifying transistor TRampA, the voltage of the vertical signal line Vlin1 follows the gate voltage of the amplifying transistor TRamp, and thus the pixel signal of the signal level Ssig22 is output to the column ADC circuit 4 via the vertical signal line Vlin1. Then, a difference between the pixel signal of the signal level Ssig22 and the pixel signal of the reset level Srst12 is obtained, and thus a signal component according to the charges accumulated in the photoelectric conversion unit PD_B1 is detected. Further, the potential of the photo gate TPGb1 may be raised before the read transistor TGb1 is turned on, the potential of the photo gate TPGb1 may be fallen after the read transistor TGb1 is turned on, and the potential of the photo gate TPGb1 may be returned to the intermediate level after the read transistor TGb1 is turned off.

As the reset transistor TRrst is turned on after the pixel signal of the signal level Ssig22 is output to the vertical signal line Vlin1, the charges of the floating diffusions FDA1, FDA2, and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst23 of the floating diffusions FD1, FD2, and FDm is applied to the gate of the amplifying transistor TRamp, the voltage of the vertical signal line Vlin1 follows the gate voltage of the amplifying transistor TRamp, and thus the pixel signal of the reset level Srst23 is output to the column ADC circuit 4 via the vertical signal line Vlin1.

Then, when the read transistor TGgr2 is turned on, the charges e accumulated in the photoelectric conversion unit PD_Gr2 are transferred to the floating diffusions FDA1, FDA2, and FDAm. Then, as a voltage according to a signal level Ssig23 of the floating diffusions FDA1, FDA2, and FDAm is applied to the gate of the amplifying transistor TRamp, the voltage of the vertical signal line Vlin1 follows the gate voltage of the amplifying transistor TRamp, and thus the pixel signal of the signal level Ssig23 is output to the column ADC circuit 4 via the vertical signal, line Vlin1. Then, a difference between the pixel signal of the signal level Ssig23 and the pixel signal of the reset level Srst23 is obtained, and thus a signal component according to the charges accumulated in the photoelectric conversion unit PD_Gr2 is detected. Further, the potential of the photo gate TPGgr2 may be raised before the read transistor TGgr2 is turned on, the potential of the photo gate TPGgr2 may be fallen after the read transistor TGgr2 is turned on, and the potential of the photo gate TPGgr2 may be returned to the intermediate level after the read transistor TGgr2 is turned off.

After the pixel signal of the signal level Ssig23 is output to the vertical signal line Vlin1, the reset transistor TRrst is turned on, and thus the charges of the floating diffusions FDA1, FDA2, and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst24 of the floating diffusions FD1, FD2, and FDm is applied to the gate of the amplifying transistor TRamp, and the voltage of the vertical signal line Vlin1 follows the gate voltage of the amplifying transistor TRamp, the pixel signal of the reset level Srst24 is output to the column ADC circuit 4 via the vertical signal line Vlin1.

Then, when the read transistor TGb2 is turned on, the charges e accumulated in the photoelectric conversion unit PD_B2 are transferred to the floating diffusions FDA1, FDA2, and FDAm. Then, as a voltage according to a signal level Ssig24 of the floating diffusions FDA1, FDA2, and FDAm is applied to the gate of the amplifying transistor TRampA, the voltage of the vertical signal line Vlin1 follows the gate voltage of the amplifying transistor TRamp, and thus the pixel signal of the signal level Ssig24 is output to the column ADC circuit 4 via the vertical signal line Vlin1. Then, a difference between the pixel signal of the signal level Ssig24 and the pixel signal of the reset level Srst24 is obtained, and thus a signal component according to the charges accumulated in the photoelectric conversion unit PD_B2 is detected. Further, the potential of the photo gate TPGgr2 may be raised before the read transistor TGgr2 is turned on, the potential of the photo gate TPGgr2 may be fallen after the read transistor TGgr2 is turned on, and the potential of the photo gate TPGgr2 may be returned to the intermediate level after the read transistor TGgr2 is turned off.

Here, as the capacities of the floating diffusions FD1, FD2, and FDm are combined with each other, and the potentials of the floating diffusions FD1, FD2, and FDm are set to the intermediate level, it is possible to suppress the degradation of an image quality caused by white spots, a leakage current, or the like while suppressing a reduction in the saturation electron numbers of the floating diffusions FD1, FD2, and FDm and the photoelectric conversion units PD_Gr1, PD_B1, PD_Gr2, and PD_B2, and it is possible to obtain an appropriate image quality at the time of intermediate luminance shooting.

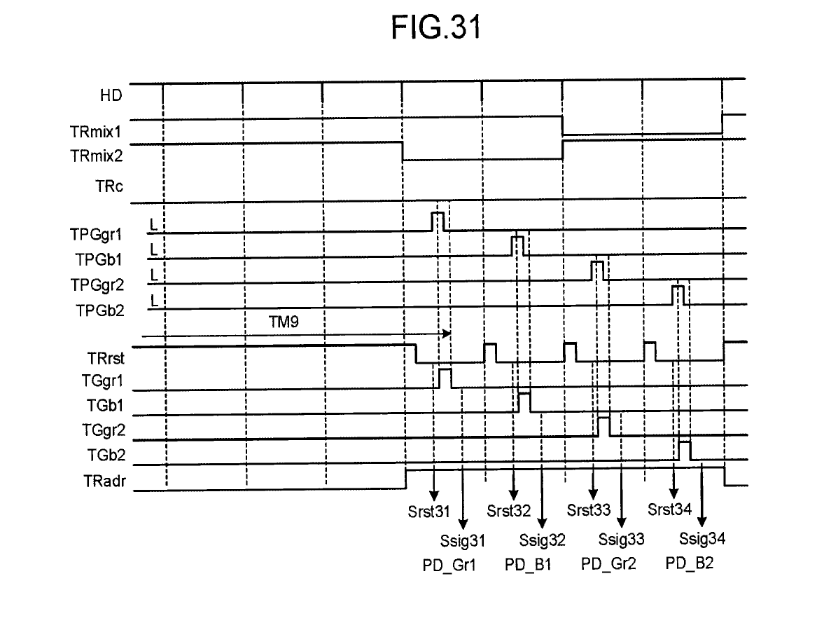

FIG. 31 is a timing chart illustrating voltage waveforms of the respective components when the pixel of FIGS. 28A and 28B performs the third read operation.

In FIG. 31, in the third read operation, as the potentials of the photo gates TPGgr1, TPGb1, TPGgr2, and TPGb2 are set to the low level L, the potentials of the photoelectric conversion units PD_Gr1, PD_B1, PD_Gr2, and PD_B2 are set to be shallow. Further, as the coupling transistor TRc is turned off, the capacitor Cp is separated from the floating diffusion FDm.

Then, as the division transistor TRmix1 is turned on, and the division transistor TRmix2 is turned off, the capacities of the floating diffusions FD1 and FDm are combined with each other, and the capacities of the floating diffusions FD2 and FDm are separated from each other. Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst31 of the floating diffusions FD1 and FDm is applied to the gate of the amplifying transistor TRamp, the voltage of the vertical signal line Vlin1 follows the gate voltage of the amplifying transistor TRamp, and thus the pixel signal of the reset level Srst31 is output to the column ADC circuit 4 via the vertical signal line Vlin1.

Then, when the read transistor TGgr1 is turned on, the charges e accumulated in the photoelectric conversion unit PD_Gr1 are transferred to the floating diffusions FDA1 and FDAm. Then, as a voltage according to a signal level Ssig31 of the floating diffusions FDA1 and FDAm is applied to the gate of the amplifying transistor TRamp, the voltage of the vertical signal line Vlin1 follows the gate voltage of the amplifying transistor TRamp, and thus the pixel signal of the signal level Ssig31 is output to the column ADC circuit 4 via the vertical signal line Vlin1. Then, a difference between the pixel signal of the signal level Ssig31 and the pixel signal of the reset level Srst31 is obtained, and thus a signal component according to the charges accumulated in the photoelectric conversion unit PD_Gr1 is detected. At this time, the accumulation period of time of the photoelectric conversion unit PD_Gr1 is TM9. Further, the potential of the photo gate TPGgr1 may be raised before the read transistor TGgr1 is turned on, and the potential of the photo gate TPGgr1 may be fallen after the read transistor TGgr1 is turned on. Here, as the potential of the photo gate TPGgr1 is raised before the read transistor TGgr1 is turned on, it is possible to form the potential gradient in the depth direction of the photoelectric conversion unit PD_Gr1, and it is possible to efficiently transfer the charges from the bottom of the photoelectric conversion unit PD_Gr1 to the front surface side.

After the pixel signal of the signal level Ssig31 is output to the vertical signal line Vlin1, the reset transistor TRrst is turned on, and thus the charges of the floating diffusions FDA1 and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst32 of the floating diffusions FD1 and FDm is applied to the gate of the amplifying transistor TRamp, the voltage of the vertical signal line Vlin1 follows the gate voltage of the amplifying transistor TRamp, and thus the pixel signal of the reset level Srst32 is output to the column ADC circuit 4 via the vertical signal line Vlin1.

Then, when the read transistor TGb1 is turned on, the charges e accumulated in the photoelectric conversion unit PD_B1 are transferred to the floating diffusions FDA1 and FDAm. Then, as a voltage according to a signal level Ssig32 of the floating diffusions FDA1 and FDAm is applied to the gate of the amplifying transistor TRampA, the voltage of the vertical signal line Vlin1 follows the gate voltage of the amplifying transistor TRamp, and thus the pixel signal of the signal level Ssig32 is output to the column ADC circuit 4 via the vertical signal line Vlin1. Then, a difference between the pixel signal of the signal level Ssig32 and the pixel signal of the reset level Srst32 is obtained, and thus a signal component according to the charges accumulated in the photoelectric conversion unit PD_B1 is detected. Further, the potential of the photo gate TPGb1 may be raised before the read transistor TGb1 is turned on, and the potential of the photo gate TPGb1 may be fallen after the read transistor TGb1 is turned on.

Then, as the division transistor TRmix1 is turned off, and the division transistor TRmix2 is turned on after the pixel signal of the signal level Ssig32 is output to the vertical signal line Vlin1, the capacities of the floating diffusions FD2 and FDm are combined with each other, and the capacities of the floating diffusions FD1 and FDm are separated from each other. Further, as the reset transistor TRrst is turned on, the charges of the floating diffusions FDA1 and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst33 of the floating diffusions FD2 and FDm is applied to the gate of the amplifying transistor TRamp, the voltage of the vertical signal line Vlin1 follows the gate voltage of the amplifying transistor TRamp, and thus the pixel signal of the reset level Srst33 is output to the column ADC circuit 4 via the vertical signal line Vlin1.

Then, when the read transistor TGgr2 is turned on, the charges e accumulated in the photoelectric conversion unit PD_Gr2 are transferred to the floating diffusions FDA2 and FDAm. Then, as a voltage according to a signal level Ssig33 of the floating diffusions FDA2 and FDAm is applied to the gate of the amplifying transistor TRamp, the voltage of the vertical signal line Vlin1 follows the gate voltage of the amplifying transistor TRamp, and thus the pixel signal of the signal level Ssig33 is output to the column ADC circuit 4 via the vertical signal line Vlin1. Then, a difference between the pixel signal of the signal level Ssig33 and the pixel signal of the reset level Srst33 is obtained, and thus a signal component according to the charges accumulated in the photoelectric conversion unit PD_Gr2 is detected. Further, the potential of the photo gate TPGgr2 may be raised before the read transistor TGgr2 is turned on, and the potential of the photo gate TPGgr2 may be fallen after the read transistor TGgr2 is turned on.

After the pixel signal of the signal level Ssig33 is output to the vertical signal line Vlin1, the reset transistor TRrst is turned on, and thus the charges of the floating diffusions FDA2 and FDAm are discharged.

Then, if the row selecting transistor TRadr is turned on when the read transistors TGgr1, TGgr2, TGb1, and TGb2 are in the off state, the power potential VDD is applied to the drain of the amplifying transistor TRamp, and thus the amplifying transistor TRamp performs the source follower operation. Then, as a voltage according to a reset level Srst34 of the floating diffusions FD2 and FDm is applied to the gate of the amplifying transistor TRamp, the voltage of the vertical signal line Vlin1 follows the gate voltage of the amplifying transistor TRamp, and thus the pixel signal of the reset level Srst34 is output to the column ADC circuit 4 via the vertical signal line Vlin1.

Then, when the read transistor TGb2 is turned on, the charges e accumulated in the photoelectric conversion unit PD_B2 are transferred to the floating diffusions FDA2 and FDAm. Then, as a voltage according to a signal level Ssig34 of the floating diffusions FDA2 and FDAm is applied to the gate of the amplifying transistor TRamp, the voltage of the vertical signal line Vlin1 follows the gate voltage of the amplifying transistor TRamp, and thus the pixel signal of the signal level Ssig34 is output to the column ADC circuit 4 via the vertical signal line Vlin1. Then, a difference between the pixel signal of the signal level Ssig34 and the pixel signal of the reset level Srst34 is obtained, and thus a signal component according to the charges accumulated in the photoelectric conversion unit PD_B2 is detected. Further, the potential of the photo gate TPGb2 may be raised before the read transistor TGb2 is turned on, and the potential of the photo gate TPGb2 may be fallen after the read transistor TGb2 is turned on.

Here, it is possible to increase the conversion gain by separating the capacities of the floating diffusions FD1, FD2, and FDm from one another, it is possible to reduce the degradation of an image quality caused by white spots, a leakage current, or the like by causing the potentials of the photoelectric conversion units PD_Gr1, PD_B1, PD_Gr2, and PD_B2 to be shallow, and it is possible to improve the image quality at the time of low luminance shooting.

### Seventeenth Embodiment

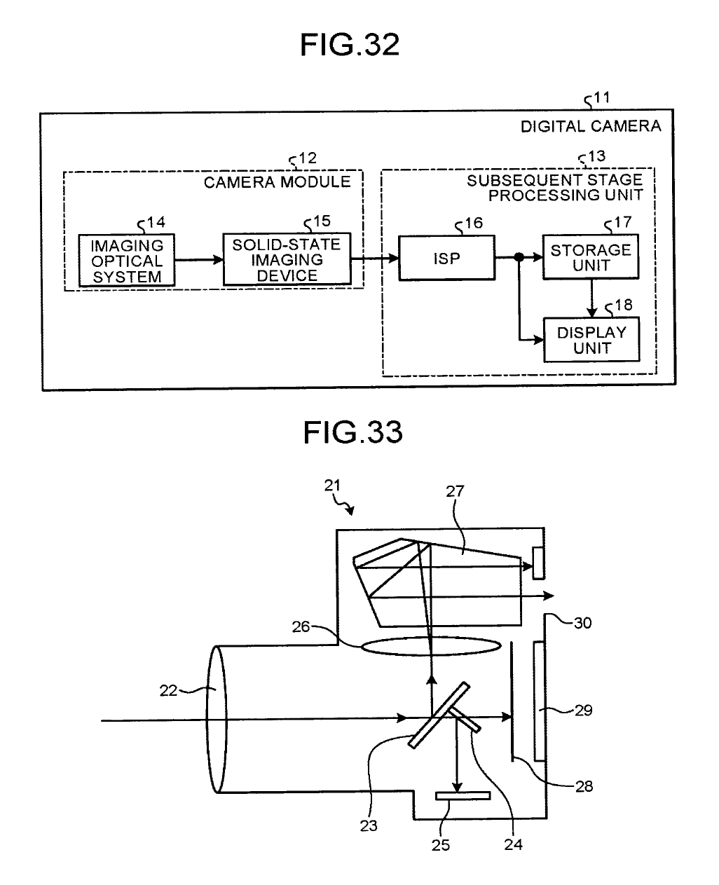

FIG. 32 is a block diagram illustrating a schematic configuration of a digital camera to which a solid-state imaging device is applied according to a seventeenth embodiment.

Referring to FIG. 32, a digital camera 11 includes a camera module 12 and a subsequent stage processing unit 13. The camera module 12 includes an imaging optical system 14 and a solid-state imaging device 15. The subsequent stage processing unit 13 includes an image signal processor (ISP) 16, a storage unit 17, and a display unit 18. At least a part of the ISP 16 may be integrated into one chip together with the solid-state imaging device 15. As the solid-state imaging device 15, for example, any one configuration of FIG. 1, FIG. 8, FIG. 13, FIG. 15, FIGS. 19 to 22, FIGS. 23A to 27A, and FIG. 31A may be used.

The imaging optical system 14 acquires light from a subject, and forms a subject image. The solid-state imaging device 15 images a subject image. The ISP 16 performs signal processing on an image signal obtained by the imaging by the solid-state imaging device 15. The storage unit 17 stores an image that has been subjected to the signal processing of the ISP 16. The storage unit 17 outputs the image signal to the display unit 18 according to the user's operation or the like. The display unit 18 displays an image according to the image signal input from the ISP 16 or the storage unit 17. The display unit 18 is, for example, a liquid crystal display. The camera module 12 can be applied to, for example, an electronic device such as a mobile terminal with a camera as well as the digital camera 11.

### Eighteenth Embodiment

FIG. 33 is a cross-sectional view illustrating a schematic configuration of a camera module to which a solid-state imaging device is applied according to an eighteenth embodiment.

Referring to FIG. 33, light incident on a lens 22 of a camera module 21 from a subject passes through a main mirror 23, a sub mirror 24, and a mechanical shutter 28 and is then incident on a solid-state imaging device 29.

The light reflected by the sub mirror 24 is incident on an auto focus (AF) sensor 25. The camera module 21 performs a focusing operation based on a detection result of the AF sensor 25. The light reflected by the main mirror 23 passes through a lens 26 and a prism 27 and is then incident on a finder 30.

The above embodiments have been described in connection with a color sensor in which the pixels PC configures the Bayer array but may be applied to a monochrome sensor. The pixels PC may be arranged in a square form or may be arranged in a 45°-inclined honeycomb form. Further, the row selecting transistor may be disposed in the pixel PC, and the row selecting transistor may not be disposed in the pixel PC. Further, the above embodiments may be applied to a 2-pixel 1-cell configuration, a 1-pixel 1-cell configuration, or a 4-pixel 1-cell configuration. Furthermore, the above embodiments may be applied to a configuration in which a column ADC circuit is mounted, and a digital signal is output or may be applied to a configuration in which no column ADC circuit is mounted, and an analog signal is output.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a pixel that includes a photoelectric conversion unit accumulating charges obtained by photoelectric conversion, the photoelectric conversion unit being disposed in a semiconductor substrate;
a photo gate that controls potential of the photoelectric conversion unit from a plane opposite to a light incident plane of the photoelectric conversion unit;
a voltage converting unit that converts signal charges read from the photoelectric conversion unit into a voltage; and
a capacity control unit that controls a capacity of the voltage converting unit.

2. The solid-state imaging device according to claim 1,
wherein the capacity control unit connects a coupling transistor to the voltage converting unit, and connects a capacitor to the coupling transistor.

3. The solid-state imaging device according to claim 1,
wherein the capacity control unit includes a switching transistor that connects a plurality of voltage converting units.

4. The solid-state imaging device according to claim 3,
wherein two switching transistors are connected in series between the voltage converting units of the neighboring pixels.

5. The solid-state imaging device according to claim 3,
wherein the voltage converting unit includes
a first voltage converting unit that is shared by a first pixel and a second pixel that neighbor in a column direction, and
a second voltage converting unit that is shared by a third pixel and a fourth pixel that neighbor in the column direction, and
the switching transistor includes a first switching transistor that connects the first voltage converting unit with the second voltage converting unit.

6. The solid-state imaging device according to claim 1,
wherein the capacity control unit includes a division transistor that divides the voltage converting unit that converts the charges generated by the pixel into a voltage into a first voltage converting unit and a second voltage converting unit.

7. The solid-state imaging device according to claim 6,
wherein the pixel includes
a read transistor that reads the signal charges generated by the photoelectric conversion unit out to the voltage converting unit,
an amplifying transistor that amplifies the signal voltage converted by the voltage converting unit, and
a reset transistor that resets the voltage converting unit, and
the division transistor divides the voltage converting unit into the first voltage converting unit at the read transistor side and the second voltage converting unit at the amplifying transistor side.

8. The solid-state imaging device according to claim 7,
wherein the photoelectric conversion unit is connected to the voltage converting unit via the read transistor, and
the read transistor is connected to a gate of the amplifying transistor via the division transistor.

9. The solid-state imaging device according to claim 8,
wherein the reset transistor is connected to the second voltage converting unit.

10. The solid-state imaging device according to claim 9, further comprising,
a row selecting transistor that is connected to the amplifying transistor in series.

11. The solid-state imaging device according to claim 7,
wherein the amplifying transistor and the voltage converting unit are shared by a first pixel, a second pixel, a third pixel, and a fourth pixel that are sequentially arranged in the column direction,
the first pixel includes
a first photoelectric conversion unit that generates charges by photoelectric conversion and
a first read transistor that reads the charges generated by the first photoelectric conversion unit out to the voltage converting unit,
the second pixel includes
a second photoelectric conversion unit that generates charges by photoelectric conversion and
a second read transistor that reads the charges generated by the second photoelectric conversion unit out to the voltage converting unit,
the third pixel includes
a third photoelectric conversion unit that generates charges by photoelectric conversion and
a third read transistor that reads the charges generated by the third photoelectric conversion unit out to the voltage converting unit,
the fourth pixel includes
a fourth photoelectric conversion unit that generates charges by photoelectric conversion and
a fourth read transistor that reads the charges generated by the fourth photoelectric conversion unit out to the voltage converting unit, and
the division transistor includes
a first division transistor that divides the voltage converting unit into a third voltage converting unit at the first read transistor side and the second read transistor side and the second voltage converting unit and
a second division transistor that divides the voltage converting unit into a fourth voltage converting unit at the third read transistor side and the fourth read transistor side and the second voltage converting unit.

12. A solid-state imaging device, comprising:
a pixel that includes a first photoelectric conversion unit disposed at a light incident plane and a second photoelectric conversion unit disposed at a plane side opposite to the light incident plane; and
a photo gate that controls the potential of the second photoelectric conversion unit.

13. The solid-state imaging device according to claim 12,
wherein the potential of the second photoelectric conversion unit is deeper than potential of the first photoelectric conversion unit.

14. The solid-state imaging device according to claim 13,
wherein the charges accumulated in the second photoelectric conversion unit are discharged, and then the charges accumulated in the first photoelectric conversion unit are read.

15. The solid-state imaging device according to claim 12,
wherein the charges accumulated in the second photoelectric conversion unit are read, and then the charges accumulated in the first photoelectric conversion unit are read.

16. The solid-state imaging device according to claim 15,
wherein the second photoelectric conversion unit corresponds to a red photoelectric conversion unit, and the first photoelectric conversion unit corresponds to a blue photoelectric conversion unit.

17. The solid-state imaging device according to claim 12,
wherein the second photoelectric conversion unit is shorter in an accumulation period of time than the first photoelectric conversion unit.

18. The solid-state imaging device according to claim 17, further comprising:
a first line memory that transfers a signal detected from the first photoelectric conversion unit; and
a second line memory that transfers a signal detected from the second photoelectric conversion unit.

19. A solid-state imaging device, comprising:
a pixel that includes a photoelectric conversion unit accumulating charges obtained by photoelectric conversion, the photoelectric conversion unit being disposed in a semiconductor substrate;
a photo gate that controls potential of the photoelectric conversion unit from a plane opposite to a light incident plane of the photoelectric conversion unit; and
a timing control circuit that controls a voltage applied to the photo gate based on an incident light quantity of the pixel.

20. The solid-state imaging device according to claim 19,
wherein the timing control circuit controls a voltage of the photo gate such that potential of the photoelectric conversion unit when an incident light quantity of the photoelectric conversion unit is small is shallower than when the incident light quantity of the photoelectric conversion unit is large.
